(19) United States
(12) Patent Application Publication
(10) Pub. No.: US 2011/0121435 A1
(43) Pub. Date: May 26, 2011

(54) PHOTOSENSITIVE ADHESIVE COMPOSITION, FILMY ADHESIVE, ADHESIVE SHEET, ADHESIVE PATTERN, SEMICONDUCTOR WAFER WITH ADHESIVE LAYER, SEMICONDUCTOR DEVICE, AND PROCESS FOR PRODUCING SEMICONDUCTOR DEVICE

(76) Inventors: Kazuyuki Mitsukura, Ibaraki (JP); Takashi Kawamori, Ibaraki (JP); Takashi Masuko, Ibaraki (JP); Shigeki Katogi, Ibaraki (JP)

(21) Appl. No.: 12/863,068

(22) PCT Filed: Jan. 9, 2009
(86) PCT No.: PCT/JP2009/050235

§ 371 Date: Jan. 7, 2011

(30) Foreign Application Priority Data
Jan. 16, 2008 (JP) 2008-006782

(51) Int. Cl. H01L 25/00; C08J 3/28; B32B 3/30; H01L 21/50

(52) U.S. Cl. 257/632; 522/50; 428/172; 438/118; 257/E25.001; 257/E21.499

(57) ABSTRACT

A photosensitive adhesive composition that comprises (A) a resin with a carboxyl and/or hydroxyl group, (B) a thermosetting resin, (C) a radiation-polymerizable compound and (D) a photoinitiator, wherein the 3% weight reduction temperature of the entire photoinitiator mixture in the composition is 200° C. or greater.

### TECHNICAL FIELD

The present invention relates to a photosensitive adhesive composition, a film-like adhesive, an adhesive sheet, an adhesive pattern, a semiconductor wafer with an adhesive layer, a semiconductor device and a process for producing a semiconductor device.

### BACKGROUND ART

Adhesives have conventionally been used in the manufacture of semiconductor devices such as semiconductor packages, for bonding between semiconductor elements and support substrates for mounting a semiconductor element. From the viewpoint of reliability for semiconductor devices, such adhesives must exhibit heat resistance and humidity-resistant reliability in order to satisfactorily ensure solder reflow resistance. Methods also exist for bonding by a step of attaching a film-like adhesive to a semiconductor wafer or the like, in which case low-temperature attachment properties are required to minimize thermal damage to adherends. Various forms of semiconductor packages have been proposed in recent years for increasing high performance and high function of electronic parts, and adhesives with pattern formability in addition to the properties mentioned above are in demand, depending on the functions, forms and methods for simplifying the assembly processes of semiconductor devices. It is known that adhesive patterns can be formed using photosensitive adhesives that have photosensitive functions. Photosensitivity is a function whereby sections irradiated with light are chemically altered to become insolubilized or solubilized in aqueous solutions or organic solvents. When a photosensitive adhesive exhibiting photosensitivity is used, it is exposed through a photomask and a pattern is formed with a developing solution, thus allowing a high definition adhesive pattern to be formed.

The materials used for photosensitive adhesives having such pattern-forming functions have hitherto been polyimide resin precursors (polyamide acids) or polyimide resin-based materials, in consideration of heat resistance (for example, see Patent documents 1-3).

[Patent document 1] Japanese Unexamined Patent Publication No. 2000-290501

[Patent document 2] Japanese Unexamined Patent Publication No. 2001-329233

[Patent document 3] Japanese Unexamined Patent Publication HEI No. 11-24257

### DISCLOSURE OF THE INVENTION

### Problems to be Solved by the Invention

However, although such materials are superior in terms of heat resistance, they require high temperatures of 300° C. or greater during thermal cyclization/imidation when using polyamide acids and during working when using polyimide resins, and therefore the thermal damage on surrounding materials is significant while thermal stress also tends to occur.

It has been attempted, incidentally, to improve low-temperature workability and soldering heat resistance by combining and crosslinking thermosetting resins with adhesives comprising polyimide resins and the like. However, it has been difficult with such methods to simultaneously achieve high levels of both pattern formability with alkali developing solutions and low-temperature attachment properties onto adherends. Moreover, it has been difficult to achieve re-heat contact bondability after pattern formation and sufficiently high adhesive force after curing with the conventional materials mentioned above. The patterning property has also posed problems, in that a high exposure dose is required due to low sensitivity.

It is an object of the present invention, which has been accomplished in light of the aforementioned problems of the prior art, to provide a photosensitive adhesive composition with excellent pattern formability, adhesion after pattern formation, heat resistance after bonding, and excellent low-temperature attachment properties after being formed into a film, as well as a film-like adhesive, an adhesive sheet, an adhesive pattern, a semiconductor wafer with an adhesive layer, a semiconductor device and a process for producing a semiconductor device, which employ the photosensitive adhesive composition.

### Means for Solving the Problems

In order to achieve the object stated above, the invention provides a photosensitive adhesive composition that comprises (A) a resin with a carboxyl and/or hydroxyl group, (B) a thermosetting resin, (C) a radiation-polymerizable compound and (D) a photoinitiator, wherein the 3% weight reduction temperature of the entire photoinitiator mixture in the composition is 200° C. or greater.

The 3% weight reduction temperature is the temperature at which the weight reduction from the initial state is 3% based on thermogravimetric analysis, and it is the 3% weight reduction temperature as measured for the photoinitiator using a Simultaneous Thermogravimetric Differential Thermal Analyzer (TG/DTA6300 by SII NanoTechnology Inc.) with a temperature-elevating rate of 10° C./min and under a nitrogen flow (400 ml/min).

According to the photosensitive adhesive composition of the invention having the construction described above, it is possible to satisfy all of the requirements for pattern formability, adhesion after pattern formation, heat resistance after adhesion, and low-temperature attachment properties when the composition is formed into a film.

The present inventors conjecture that the reasons for the effects mentioned above with the photosensitive adhesive composition of the invention include the fact that the composition has a long shelf life, less outgas is generated by heat treatment after bonding, and reaction due to the temperature for application and drying is not promoted when the composition is formed into a film.

According to the invention it is also possible to realize a photosensitive adhesive composition exhibiting the effects mentioned above while also having excellent storage stability at room temperature, by combination of the aforementioned components (A), (B), (C) and (D). Unless otherwise specified, “room temperature” is 25° C.

From the viewpoint of increasing the sensitivity of pattern formability for the photosensitive adhesive composition of the invention, the (D) photoinitiator preferably contains a compound having a molar absorption coefficient of 1000 ml/g·cm or greater for light with a wavelength of 365 nm.

From the viewpoint of improving heat resistance or the like, the (D) photoinitiator in the photosensitive adhesive composition of the invention preferably contains a compound with a carbazole group.

Also from the viewpoint of improving heat resistance or the like, the (D) photoinitiator in the photosensitive adhesive composition of the invention preferably contains a compound with an oxime ester group.

The (D) photoinitiator in the photosensitive adhesive composition of the invention especially preferably contains a compound represented by the following structural formula (1), because it will react efficiently in a small amount under irradiation, and the photodecomposed fragments will be resistant to sublimation and decomposition.

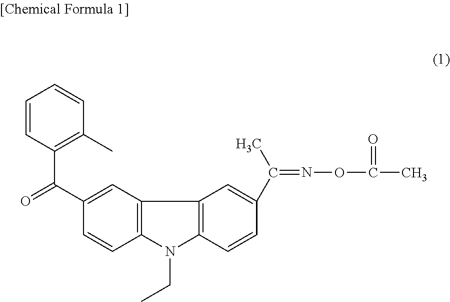

From the viewpoint of storage stability, high-temperature adhesion and heat resistance, the (B) thermosetting resin is preferably an epoxy resin.

Preferably, the (A) resin with a carboxyl and/or hydroxyl group has a glass transition temperature of not greater than 150° C. and the weight-average molecular weight of 5000-300000. The resin is preferably an alkali-soluble resin. The resin is preferably a polyimide resin.

The polyimide resin is preferably a polyimide resin obtained by reaction between a tetracarboxylic dianhydride and a diamine component containing a diamine with a carboxyl and/or hydroxyl group in a molecule. The polyimide resin is also preferably a polyimide resin obtained by reaction between a tetracarboxylic dianhydride and an aromatic diamine represented by the following structural formula (2) and/or an aromatic diamine represented by the following structural formula (3).

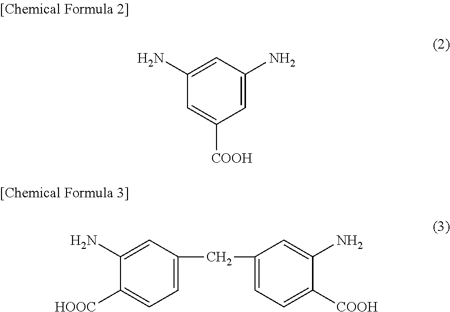

The diamine component preferably further contains an aliphatic etherdiamine represented by the following formula (4) at 10-90 mol % of the total diamine component. This will allow the glass transition temperature of the polyimide resin to be lowered and can provide alkali-solubility, solvent solubility and compatibility with other compounding ingredients.

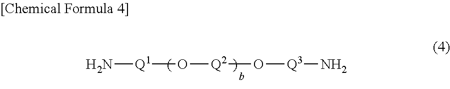

[In the formula, Q¹, Q² and Q³ each independently represent a C1-10 alkylene group, and b represents an integer of 1-80.]

From the viewpoint of providing satisfactory adhesion, the diamine component preferably further contains a siloxanediamine represented by the following formula (5) at 1-20 mol % of the total diamine component.

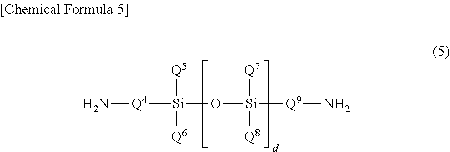

[In the formula, Q⁴ and Q⁹ each independently represent a C1-5 alkylene or optionally substituted phenylene group, Q⁵, Q⁶, Q⁷ and Q⁸ each independently represent a C1-5 alkyl, phenyl or phenoxy group, and d represents an integer of 1-5.]

From the viewpoint of optical transparency and low-temperature attachment properties, the polyimide resin is preferably a polyimide resin obtained by reaction between a tetracarboxylic dianhydride and a diamine component, with the tetracarboxylic dianhydride containing a tetracarboxylic dianhydride represented by the following formula (6) at 40 mol % or greater of the total tetracarboxylic dianhydrides.

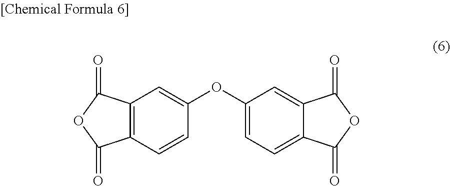

The film-like adhesive of the invention is composed of the photosensitive adhesive composition of the invention as described above. According to the film-like adhesive of the invention, which is composed of the photosensitive adhesive composition of the invention, it is possible to satisfy all of the requirements for pattern formability, adhesion after pattern formation, heat resistance after adhesion and low-temperature attachment properties, thereby increasing the efficiency of assembly process for semiconductor devices and improving reliability for semiconductor devices.

The adhesive sheet of the invention comprises a base and an adhesive layer composed of a photosensitive adhesive composition of the invention formed on one side of the base. According to the adhesive sheet of the invention, which comprises an adhesive layer composed of the photosensitive adhesive composition of the invention, it is possible to satisfy all of the requirements for pattern formability, adhesion after pattern formation, heat resistance after adhesion and low-temperature attachment properties, thereby increasing the efficiency of assembly process for semiconductor devices and improving reliability for semiconductor devices.

The adhesive sheet of the invention may also comprise the film-like adhesive of the invention and a dicing sheet, wherein the film-like adhesive and dicing sheet are laminated. Such an adhesive sheet having the configuration described above can realize a die bonding/dicing sheet that satisfies all of the requirements for pattern formability, adhesion after pattern formation, heat resistance after adhesion and low-temperature attachment properties. This will make it possible to achieve increased efficiency of assembly process for semiconductor devices and improved reliability for semiconductor devices.

The adhesive pattern of the invention is formed by forming an adhesive layer composed of the photosensitive adhesive composition of the invention on an adherend, exposing the adhesive layer to light through a photomask, and developing the exposed adhesive layer with an aqueous alkali solution. The adhesive pattern of the invention may also be formed by forming an adhesive layer composed of the photosensitive adhesive composition of the invention on an adherend, subjecting the adhesive layer directly to pattern exposure using direct pattern exposure technology, and developing the exposed adhesive layer with an aqueous alkali solution. Since the photosensitive adhesive composition of the invention has excellent pattern formability, the adhesive pattern of the invention can be imparted with a high definition pattern by formation from the photosensitive adhesive composition of the invention, and re-adhesion property after exposure is also excellent. The adhesive pattern of the invention can also provide excellent heat resistance after adhesion.

The semiconductor wafer with an adhesive layer according to the invention comprises a semiconductor wafer and an adhesive layer composed of the photosensitive adhesive composition of the invention, formed on one side of the semiconductor wafer. A semiconductor wafer with an adhesive layer of the invention, which comprises an adhesive layer composed of a photosensitive adhesive composition of the invention, allows pattern formation of the adhesive layer while also exhibiting excellent adhesion after pattern formation and heat resistance after adhesion, and can therefore increase the efficiency of assembly process for semiconductor devices and improve the reliability of semiconductor devices.

The semiconductor device of the invention comprises a supporting member, a semiconductor element mounted on the supporting member and an adhesive layer situated between the supporting member and semiconductor element, wherein the adhesive layer is formed of the photosensitive adhesive composition of the invention as described above. Since the semiconductor device of the invention comprises a semiconductor element and a supporting member bonded by a photosensitive adhesive composition of the invention which has excellent pattern formability, adhesion after pattern formation, and heat resistance (high-temperature adhesion) after adhesion, it can satisfactorily simplify the production process while also exhibiting excellent reliability.

The process for producing a semiconductor device of the invention comprises a step of bonding a semiconductor element and a supporting member for mounting a semiconductor element by the photosensitive adhesive composition of the invention. The process for producing a semiconductor device according to the invention, which employs a photosensitive adhesive composition of the invention, can also provide semiconductor devices with excellent reliability. In addition, the process for producing a semiconductor device according to the invention allows reliable production of semiconductor devices with various functions and shapes to be accomplished.

### EFFECT OF THE INVENTION

According to the invention it is possible to provide a photosensitive adhesive composition with excellent pattern formability, sensitivity, adhesion after pattern formation, heat resistance and humidity-resistant reliability after bonding, and excellent low-temperature attachment properties after being formed into a film, as well as a film-like adhesive, an adhesive sheet, an adhesive pattern, a semiconductor wafer with an adhesive layer, a semiconductor device and a process for producing a semiconductor device, which employ the photosensitive adhesive composition. In addition, it is possible to provide a resin composition that has re-heat contact bondability with pattern-formed adherends such as boards, glass and semiconductor elements, as well as excellent heat resistance after thermosetting, and that can thus be suitable for use to protect semiconductor elements, optical elements and solid-state imaging elements or use as an adhesive and/or buffer coat that requires microbonding regions, and therefore can improve the reliability of apparatuses comprising the resin composition.

### BRIEF DESCRIPTION OF THE DRAWINGS

FIG. 1 is a schematic cross-sectional view showing an embodiment of a film-like adhesive according to the invention.

FIG. 2 is a schematic cross-sectional view showing an embodiment of an adhesive sheet according to the invention.

FIG. 3 is a schematic cross-sectional view showing another embodiment of an adhesive sheet of the invention.

FIG. 4 is a schematic cross-sectional view showing another embodiment of an adhesive sheet of the invention.

FIG. 5 is a top view showing an embodiment of a semiconductor wafer with an adhesive layer according to the invention.

FIG. 6 is an end view along line VI-VI in FIG. 5.

FIG. 7 is a top view showing an embodiment of an adhesive pattern according to the invention.

FIG. 8 is an end view along line VIII-VIII in FIG. 7.

FIG. 9 is a top view showing an embodiment of an adhesive pattern according to the invention.

FIG. 10 is an end view along line X-X in FIG. 9.

FIG. 11 is a schematic cross-sectional view showing an embodiment of a semiconductor device according to the invention.

FIG. 12 is a schematic cross-sectional view showing another embodiment of a semiconductor device according to the invention.

FIG. 13 is a schematic view of a peel strength tester.

### EXPLANATION OF SYMBOLS

1: Film-like adhesive (adhesive layer), 1a, 1b: adhesive patterns, 2: cover film, 3: base film (base), 6: adhesive layer, 7: base film, 8: semiconductor wafer, 12, 12a, 12b: semiconductor elements, 13: supporting member for mounting a semiconductor element, 14: wire, 15: sealing material, 16: terminal, 20, 20a, 20b: semiconductor wafers with adhesive layer, 100, 110, 120: adhesive sheets, 210: semiconductor device.

### BEST MODE FOR CARRYING OUT THE INVENTION

Preferred embodiments of the invention will now be explained in detail, with reference to the accompanying drawings as necessary. Identical or corresponding parts in the drawings will be referred to by like reference numerals and will be explained only once. Unless otherwise specified, the vertical and horizontal positional relationships are based on the positional relationships in the drawings. Also, the dimensional proportions depicted in the drawings are not necessarily limitative.

The photosensitive adhesive composition of the invention comprises (A) a resin with a carboxyl and/or hydroxyl group, (B) a thermosetting resin, (C) a radiation-polymerizable compound and (D) a photoinitiator.

Component (A) in the photosensitive adhesive composition of the invention is preferably a thermoplastic resin. Component (A) may be any of the following resins alone, or the resins with carboxyl and/or hydroxyl groups added on side chains. As examples there may be mentioned polyimide resins, polyimide resins, polyamideimide resins, polyetherimide resins, polyurethaneimide resins, polyurethaneamideimide resins, siloxanepolyimide resins, polyesterimide resins, and their copolymers and precursors (polyamide acids), as well as polyurethane resins, polybenzooxazole resins, phenoxy resins, polysulfone resins, polyethersulfone resins, polyphenylene sulfide resins, polyester resins, polyether resins, polycarbonate resins, polyetherketone resins, (meth)acrylic copolymers with weight-average molecular weights of 10000-1000000, phenol-novolac resins, cresol-novolac resins, phenol resins and the like. Any of these may be used alone or in combinations of two or more.

From the viewpoint of obtaining satisfactory developing properties, component (A) is preferably a resin with a carboxyl group and the resin is preferably an alkali-soluble resin. When the alkali-soluble group of the alkali-soluble resin is a hydroxyl group, it is preferably a phenolic hydroxyl group.

The attachment temperature for the film-like adhesive of the invention onto a wafer back side, described hereunder, is preferably 20° C. or greater, more preferably 20-150° C. and especially preferably 25-100° C., from the viewpoint of inhibiting warping of the semiconductor wafer. In order to allow attachment at such temperatures, the glass transition temperature (Tg) of component (A) is preferably not greater than 150° C. If the Tg of component (A) is greater than 150° C., the attachment temperature onto wafer back sides will tend to increase above 150° C. and warping after the attachment onto wafer back sides will tend to occur easily, while if the Tg is below −20° C., the tack property of the film surface in the B-stage state will be too strong, tending to impair the manageability. The composition of the polyimide resin described hereunder is preferably designed so that the Tg is not greater than 150° C.

The weight-average molecular weight of component (A) is preferably controlled to within 5000-300000, more preferably 5000-150000, even more preferably 10000-100000 and most preferably 10000-80000. If the weight-average molecular weight is within the range of 5000-300000, the strength, pliability and tack properties of the photosensitive adhesive composition formed into a sheet or film will be satisfactory, while the hot flow property will also be satisfactory, thus helping to ensure good embedding properties in wiring steps on the board surface. If the weight-average molecular weight is less than 5000, the film formability will tend to be impaired, while if it is greater than 300000; the hot flow property will be poor, the embedding property into irregularities on the board will tend to be reduced, and the solubility of the resin composition in the alkali developing solution will tend to be lower.

If the Tg and weight-average molecular weight of component (A) are within these ranges, it will be possible to lower the attachment temperature onto wafer back sides while also lowering the heating temperature (die bonding temperature) for adhesive anchoring of the semiconductor element to the supporting member for mounting a semiconductor element, and to inhibit increase in warping of the semiconductor element. It will also be possible to effectively impart a flow property and developing property for die bonding, as a feature of the invention.

The Tg is the primary dispersion peak temperature when component (A) is formed into a film, and the primary dispersion temperature is obtained by measurement of the tan δ peak temperature near Tg using a viscoelasticity analyzer “RSA-2” (trade name) by Rheometrix, under conditions with a temperature-elevating rate of 5° C./min, a frequency of 1 Hz and a measuring temperature of −150 to 300° C. The weight-average molecular weight is the weight-average molecular weight measured in terms of polystyrene using a high-performance liquid chromatograph “C-R4A” (trade name) by Shimadzu Corp.

Component (A) is preferably a polyimide resin from the viewpoint of heat resistance and adhesion. The polyimide resin may be obtained, for example, by condensation reaction of a tetracarboxylic dianhydride and diamine component by a known process. Specifically, the compositional ratio is adjusted in the organic solvent so that the tetracarboxylic dianhydride and diamine component are in equimolar amounts, or if necessary so that the total of diamine component is in the range of preferably 0.5-2.0 mol and more preferably 0.8-1.0 mol with respect to 1.0 mol as the total tetracarboxylic dianhydrides (with any desired order of addition of the components), and addition reaction is conducted with a reaction temperature of not greater than 80° C. and preferably 0-60° C. The viscosity of the reaction mixture will gradually increase as the reaction proceeds, forming polyamide acid as the polyimide resin precursor. In order to prevent reduction in the properties of the adhesive composition, the tetracarboxylic dianhydride is preferably one that has been subjected to recrystallizing purifying treatment with acetic anhydride.

If total diamine component exceeds 2.0 mol with respect to 1.0 mol as the total tetracarboxylic dianhydrides, in the compositional ratio of the tetracarboxylic dianhydride and diamine component for the condensation reaction, the amount of amine-terminal polyimide oligomers in the obtained polyimide resin will tend to be greater and the weight-average molecular weight of the polyimide resin will be reduced, thus tending to lower the properties of the adhesive composition including the heat resistance. On the other hand, if total diamine component is less than 0.5 mol, the amount of acid-terminal polyimide oligomers will tend to be greater and the weight-average molecular weight of the polyimide resin will be reduced, thus tending to lower the properties of the adhesive composition including the heat resistance.

The polyimide resin can be obtained by dehydrating cyclization of the reaction product (polyamide acid). Dehydrating cyclization can be accomplished by thermal cyclization using heat treatment or by chemical cyclization using a dehydrating agent.

There are no particular restrictions on tetracarboxylic dianhydrides to be used as starting materials for the polyimide resin, and as examples there may be mentioned pyromellitic acid dianhydride, 3,3′,4,4′-biphenyltetracarboxylic dianhydride, 2,2′,3,3′-biphenyltetracarboxylic dianhydride, 2,2-bis(3,4-dicarboxyphenyl)propane dianhydride, 2,2-bis(2,3-dicarboxyphenyl)propane dianhydride, 1,1-bis(2,3-dicarboxyphenyl)ethane dianhydride, 1,1-bis(3,4-dicarboxyphenyl)ethane dianhydride, bis(2,3-dicarboxyphenyl)methane dianhydride, bis(3,4-dicarboxyphenyl)methane dianhydride, bis(3,4-dicarboxyphenyl)sulfone dianhydride, 3,4,9,10-perylenetetracarboxylic dianhydride, bis(3,4-dicarboxyphenyl)ether dianhydride, benzene-1,2,3,4-tetracarboxylic dianhydride, 3,4,3′,4′-benzophenonetetracarboxylic dianhydride, 2,3,2′,3′-benzophenonetetracarboxylic dianhydride, 3,3,3′,4′-benzophenonetetracarboxylic dianhydride, 1,2,5,6-naphthalenetetracarboxylic dianhydride, 1,4,5,8-naphthalenetetracarboxylic dianhydride, 2,3,6,7-naphthalenetetracarboxylic dianhydride, 1,2,4,5-naphthalenetetracarboxylic dianhydride, 2,6-dichloronaphthalene-1,4,5,8-tetracarboxylic dianhydride, 2,7-dichloronaphthalene-1,4,5,8-tetracarboxylic dianhydride, 2,3,6,7-tetrachloronaphthalene-1,4,5,8-tetracarboxylic dianhydride, phenanthrene-1,8,9,10-tetracarboxylic dianhydride, pyrazine-2,3,5,6-tetracarboxylic dianhydride, thiophene-2,3,5,6-tetracarboxylic dianhydride, 2,3,3′,4′-biphenyltetracarboxylic dianhydride, 3,4,3′,4′-biphenyltetracarboxylic dianhydride, 2,3,2′,3′-biphenyltetracarboxylic dianhydride, bis(3,4-dicarboxyphenyl)dimethylsilane dianhydride, bis(3,4-dicarboxyphenyl)methylphenylsilane dianhydride, bis(3,4-dicarboxyphenyl)diphenylsilane dianhydride, 1,4-bis(3,4-dicarboxyphenyldimethylsilyl)benzene dianhydride, 1,3-bis(3,4-dicarboxyphenyl)-1,1,3,3-tetramethyldicyclohexane dianhydride, p-phenylenebis(trimellitate anhydride), ethylenetetracarboxylic dianhydride, 1,2,3,4-butanetetracarboxylic dianhydride, decahydronaphthalene-1,4,5,8-tetracarboxylic dianhydride, 4,8-dimethyl-1,2,3,5,6,7-hexahydronaphthalene-1,2,5,6-tetracarboxylic dianhydride, cyclopentane-1,2,3,4-tetracarboxylic dianhydride, pyrrolidine-2,3,4,5-tetracarboxylic dianhydride, 1,2,3,4-cyclobutanetetracarboxylic dianhydride, bis(exo-bicyclo[2,2,1]heptane-2,3-dicarboxylic dianhydride, bicyclo-[2,2,2]-oct-7-ene-2,3,5,6-tetracarboxylic dianhydride, 2,2-bis(3,4-dicarboxyphenyl)propane dianhydride, 2,2-bis[4-(3,4-dicarboxyphenyl)phenyl]propane dianhydride, 2,2-bis(3,4-dicarboxyphenyl)hexafluoropropane dianhydride, 2,2-bis[4-(3,4-dicarboxyphenyl)phenyl]hexafluoropropane dianhydride, 4,4′-bis(3,4-dicarboxyphenoxy)diphenyl sulfide dianhydride, 1,4-bis(2-hydroxyhexafluoroisopropyl)benzenebis(trimellitic anhydride), 1,3-bis(2-hydroxyhexafluoroisopropyl)benzenebis(trimellitic anhydride), 5-(2,5-dioxotetrahydrofuryl)-3-methyl-3-cyclohexene-1,2-dicarboxylic dianhydride, tetrahydrofuran-2,3,4,5-tetracarboxylic dianhydride, and tetracarboxylic dianhydrides represented by the following formula (7).

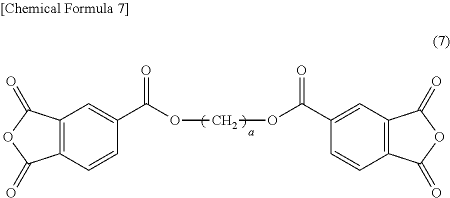

[In the formula, a represents an integer of 2-20.]

The tetracarboxylic dianhydride represented by formula (7) can be synthesized from trimellitic anhydride monochloride and its corresponding diol, for example, and specifically there may be mentioned 1,2-(ethylene)bis(trimellitate anhydride), 1,3-(trimethylene)bis(trimellitate anhydride), 1,4-(tetramethylene)bis(trimellitate anhydride), 1,5-(pentamethylene)bis(trimellitate anhydride), 1,6-(hexamethylene)bis(trimellitate anhydride), 1,7-(heptamethylene)bis(trimellitate anhydride), 1,8-(octamethylene)bis(trimellitate anhydride), 1,9-(nonamethylene)bis(trimellitate anhydride), 1,10-(decamethylene)bis(trimellitate anhydride), 1,12-(dodecamethylene)bis(trimellitate anhydride), 1,16-(hexadecamethylene)bis(trimellitate anhydride) and 1,18-(octadecamethylene)bis(trimellitate anhydride).

Preferred tetracarboxylic dianhydrides are those including tetracarboxylic dianhydrides represented by the following formula (6) or (8), from the viewpoint of imparting satisfactory solubility in the solvent and satisfactory moisture-proof reliability, and transparency to 365 nm light. The tetracarboxylic dianhydride represented by the following formula (6) is preferably used at 40 mol % or greater with respect to the total tetracarboxylic dianhydrides.

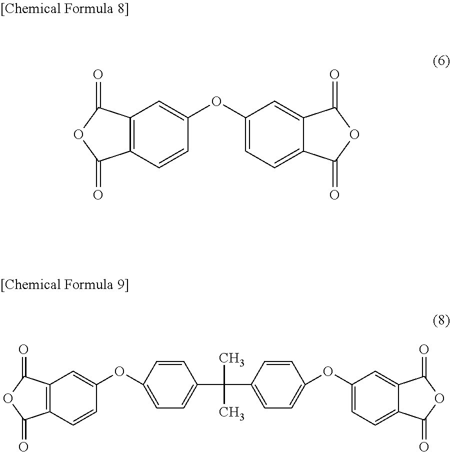

These tetracarboxylic dianhydrides may be used alone or in combinations of two or more.

The diamine component used as a starting material for the polyimide resin preferably includes a diamine with a carboxyl and/or hydroxyl group in the molecule, and preferably includes an aromatic diamine represented by the following formula (2), (3), (9) or (10). The diamines represented by the following formula (2), (3), (9) or (10) are preferably used at 1-100 mol %, more preferably 3-80 mol % and most preferably 5-50 mol % of the total diamine component.

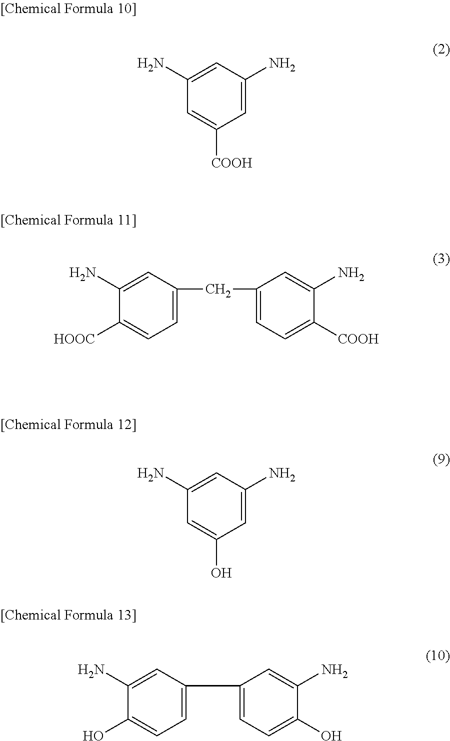

There are no particular restrictions on other diamine components to be used as starting materials for the polyimide resin, and as examples there may be mentioned aromatic diamines such as o-phenylenediamine, m-phenylenediamine, p-phenylenediamine, 3,3′-diaminodiphenyl ether, 3,4′-diaminodiphenyl ether, 4,4′-diaminodiphenyl ether, 3,3′-diaminodiphenylmethane, 3,4′-diaminodiphenylmethane, 4,4′-diaminodiphenylether methane, bis(4-amino-3,5-dimethylphenyl)methane, bis(4-amino-3,5-diisopropylphenyl)methane, 3,3′-diaminodiphenyldifluoromethane, 3,4′-diaminodiphenyldifluoromethane, 4,4′-diaminodiphenyldifluoromethane, 3,3′-diaminodiphenylsulfone, 3,4′-diaminodiphenylsulfone, 4,4′-diaminodiphenylsulfone, 3,3′-diaminodiphenyl sulfide, 3,4′-diaminodiphenyl sulfide, 4,4′-diaminodiphenyl sulfide, 3,3′-diaminodiphenylketone, 3,4′-diaminodiphenylketone, 4,4′-diaminodiphenylketone, 2,2-bis(3-aminophenyl)propane, 2,2′-(3,4′-diaminodiphenyl)propane, 2,2-bis(4-aminophenyl)propane, 2,2-bis(3-aminophenyl)hexafluoropropane, 2,2-(3,4′-diaminodiphenyl)hexafluoropropane, 2,2-bis(4-aminophenyl)hexafluoropropane, 1,3-bis(3-aminophenoxy)benzene, 1,4-bis(3-aminophenoxy)benzene, 1,4-bis(4-aminophenoxy)benzene, 3,3′-(1,4-phenylenebis(1-methylethylidene))bis aniline, 3,4′-(1,4-phenylenebis(1-methylethylidene))bis aniline, 4,4′-(1,4-phenylenebis(1-methylethylidene))bisaniline, 2,2-bis(4-(3-aminophenoxy)phenyl)propane, 2,2-bis(4-(3-aminophenoxy)phenyl)hexafluoropropane, 2,2-bis(4-(4-aminophenoxy)phenyl)hexafluoropropane, bis(4-(3-aminoenoxy)phenyl)sulfide, bis(4-(4-aminoenoxy)phenyl)sulfide, bis(4-(3-aminoenoxy)phenyl)sulfone, bis(4-(4-aminoenoxy)phenyl)sulfone, 3,3′-dihydroxy-4,4′-diaminobiphenyl and 3,5-diaminobenzoic acid, 1,3-bis(aminomethyl)cyclohexane, 2,2-bis(4-aminophenoxyphenyl)propane, aliphatic etherdiamines represented by the following formula (4), aliphatic diamines represented by the following formula (11), and siloxanediamines represented by the following formula (5).

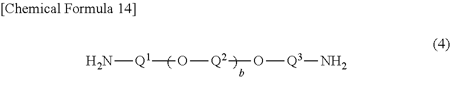

[In the formula, Q′, Q² and Q³ each independently represent a C1-10 alkylene group, and b represents an integer of 1-80.]

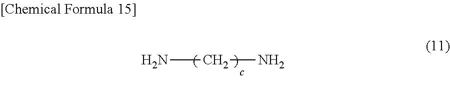

[In the formula, c represents an integer of 5-20.]

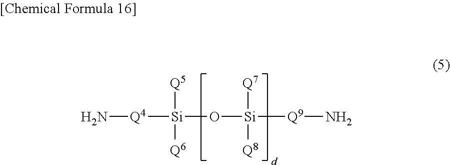

[In the formula, Q⁴ and Q⁹ each independently represent a C1-5 alkylene or optionally substituted phenylene group, Q⁵, Q⁶, Q⁷ and Q⁸ each independently represent a C1-5 alkyl, phenyl or phenoxy group, and d represents an integer of 1-5.]

As specific aliphatic etherdiamines represented by formula (4) above there may be mentioned aliphatic diamines represented by the following formula:

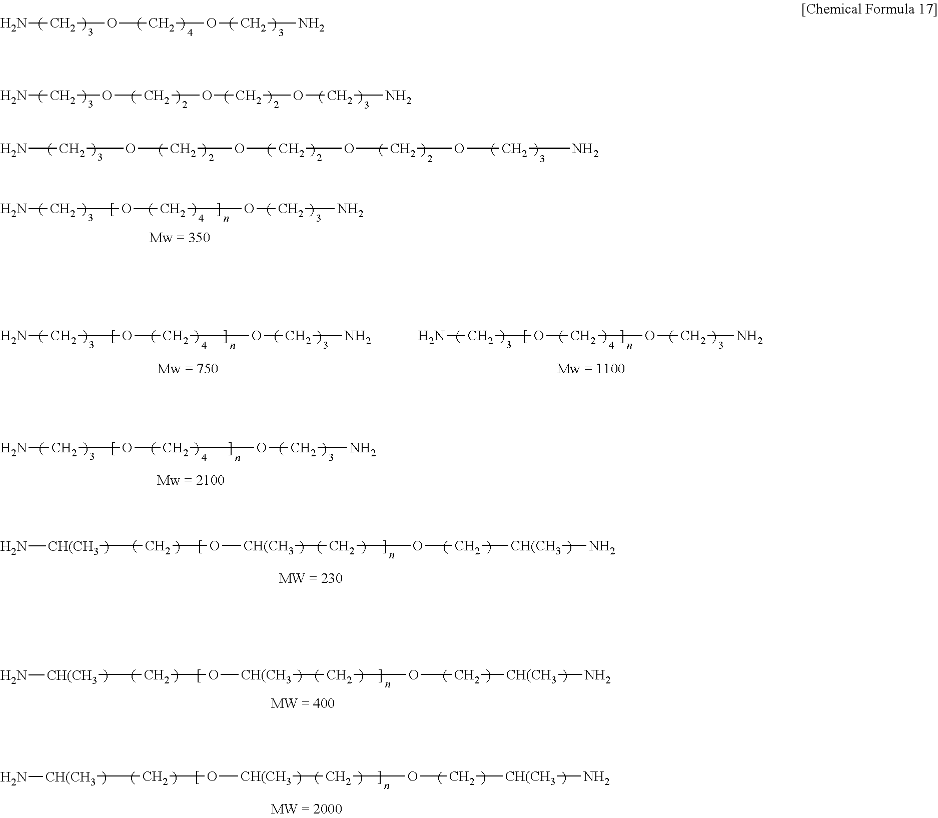

and aliphatic etherdiamines represented by the following formula (12).

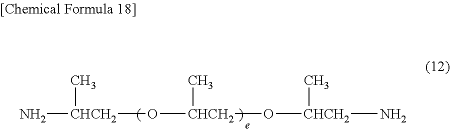

[In the formula, e represents an integer of 0-80.]

The aliphatic etherdiamine represented by formula (4) is preferably used at 10-90 mol % of the total diamine component.

As mentioned above, the composition of the polyimide resin is preferably designed so that the Tg is not greater than 150° C., and the diamine component used as a starting material for the polyimide resin is preferably the aliphatic etherdiamine represented by formula (12) above. As specific aliphatic etherdiamines represented by formula (12) there may be mentioned aliphatic diamines, including polyoxyalkylenediamines such as JEFFAMINE D-230, D-400, D-0, D-4000, ED-600, ED-900, ED-0 and EDR-148 by San Techno Chemical Co., Ltd., and polyetheramine D-230, D-400 and D-0 by BASF. These diamines is used at preferably 1-80 mol % and more preferably 5-60 mol % of the total diamine component. If the amount is less than 1 mol % it will tend to be difficult to impart low-temperature adhesion and a hot flow property, while if it is greater than 80 mol % the Tg of the polyimide resin will be too low, tending to impair the self-supporting property of the film.

As specific aliphatic diamines represented by formula (11) above there may be mentioned 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,11-diaminoundecane, 1,12-diaminododecane and 1,2-diaminocyclohexane.

As examples of siloxanediamines represented by formula (5) there may be mentioned, specifically, as compounds wherein d in formula (5) is 1: 1,1,3,3-tetramethyl-1,3-bis(4-aminophenyl)disiloxane, 1,1,3,3-tetraphenoxy-1,3-bis(4-aminoethyl)disiloxane, 1,1,3,3-tetraphenyl-1,3-bis(2-aminoethyl)disiloxane, 1,1,3,3-tetraphenyl-1,3-bis(3-aminopropyl)disiloxane, 1,1,3,3-tetramethyl-1,3-bis(2-aminoethyl)disiloxane, 1,1,3,3-tetramethyl-1,3-bis(3-aminopropyl)disiloxane, 1,1,3,3-tetramethyl-1,3-bis(3-aminobutyl)disiloxane and 1,3-dimethyl-1,3-dimethoxy-1,3-bis(4-aminobutyl)disiloxane, and as compounds wherein d is 2: 1,1,3,3,5,5-hexamethyl-1,5-bis(4-aminophenyl)trisiloxane, 1,1,5,5-tetraphenyl-3,3-dimethyl-1,5-bis(3-aminopropyl)trisiloxane, 1,1,5,5-tetraphenyl-3,3-dimethoxy-1,5-bis(4-aminobutyl)trisiloxane, 1,1,5,5-tetraphenyl-3,3-dimethoxy-1,5-bis(5-aminopentyl)trisiloxane, 1,1,5,5-tetramethyl-3,3-dimethoxy-1,5-bis(2-aminoethyl)trisiloxane, 1,1,5,5-tetramethyl-3,3-dimethoxy-1,5-bis(4-aminobutyl)trisiloxane, 1,1,5,5-tetramethyl-3,3-dimethoxy-1,5-bis(5-aminopentyl)trisiloxane, 1,1,3,3,5,5-hexamethyl-1,5-bis(3-aminopropyl)trisiloxane, 1,1,3,3,5,5-hexaethyl-1,5-bis(3-aminopropyl)trisiloxane and 1,1,3,3,5,5-hexapropyl-1,5-bis(3-aminopropyl)trisiloxane.

The aliphatic etherdiamine represented by formula (5) is preferably used at 1-20 mol % of the total diamine component.

These diamine component may be used alone or as a combination of two or more types.

The above-mentioned polyimide resins may be used alone, or if necessary they may be used as mixtures (blends) of two or more different types.

The content of component (A) in the photosensitive adhesive composition of the invention is preferably 5-90% by mass and more preferably 20-80% by mass based on the total solid mass of the photosensitive adhesive composition. If the content is less than 5% by mass the pattern formability will tend to be impaired, while if it is greater than 90% by mass the pattern formability and adhesion will tend to be reduced.

When component (A) has poor or no solubility in alkalis, a resin or compound with a carboxyl and/or hydroxyl group may be added as a solubilizing aid.

Component (B) used for the invention is a thermosetting resin (other than component (A)). An epoxy resin is preferred for component (B). Component (B) preferably contains at least two epoxy groups in the molecule, and more preferably it is a phenol glycidyl ether-type epoxy resin, from the viewpoint of curability and cured properties. As examples of such resins there may be mentioned bisphenol A-type (or AD-type, S-type or F-type) glycidyl ethers, hydrogenated bisphenol A-type glycidyl ethers, ethylene oxide adduct bisphenol A-type glycidyl ethers, propylene oxide adduct bisphenol A-type glycidyl ethers, phenol-novolac resin glycidyl ethers, cresol-novolac resin glycidyl ethers, bisphenol A-novolac resin glycidyl ethers, naphthalene resin glycidyl ethers, trifunctional (or tetrafunctional) glycidyl ethers, dicyclopentadienephenol resin glycidyl ethers, dimer acid glycidyl esters, trifunctional (or tetrafunctional) glycidylamines, naphthalene resin glycidylamines, and the like. These may be used alone or in combinations of two or more.

From the viewpoint of preventing electromigration and corrosion of metal conductor circuits, component (B) is preferably a high purity product with a content of not greater than 300 ppm for impurity ions such as alkali metal ions, alkaline earth metal ions and halide ions, and particularly chloride ion or hydrolyzable chlorine.

The content of component (B) in the photosensitive adhesive composition of the invention is preferably 0.1-100 parts by mass and more preferably 2-50 parts by mass with respect to 100 parts by mass of component (A). A content of greater than 100 parts by mass will tend to lower the solubility in the aqueous alkali solution and reduce the pattern formability. On the other hand, a content of less than 0.1 part by mass will tend to lower the high-temperature adhesion.

The photosensitive adhesive composition of the invention may also contain a curing agent for thermosetting resin if necessary. As examples of curing agents there may be mentioned phenol-based compounds, aliphatic amines, alicyclic amines, aromatic polyamines, polyamides, aliphatic acid anhydrides, alicyclic acid anhydrides, aromatic acid anhydrides, dicyandiamides, organic acid dihydrazides, boron trifluoride amine complexes, imidazoles and tertiary amines. Phenol-based compounds are preferred among these, and phenol-based compounds having two or more phenolic hydroxyl groups in the molecule are more preferred. As examples of such compounds there may be mentioned phenol-novolac, cresol-novolac, t-butylphenol-novolac, dicyclopentadienecresol-novolac, dicyclopentadienephenol-novolac, xylylene-modified phenol-novolac, naphthol-based compounds, trisphenol-based compounds, tetrakisphenol-novolac, bisphenol A-novolac, poly-p-vinylphenol and phenolaralkyl resins. Compounds with a number-average molecular weight in the range of 400-4000 are preferred among these. This will help minimize outgas during heating, which can cause contamination of the semiconductor element or apparatus during the heating for semiconductor device assembly.

The photosensitive adhesive composition of the invention may also contain a curing accelerator if necessary. The curing accelerator is not particularly restricted so long as it cures the thermosetting resin, and as examples there may be mentioned imidazoles, dicyandiamide derivatives, dicarboxylic acid dihydrazides, triphenylphosphine, tetraphenylphosphoniumtetraphenyl borate, 2-ethyl-4-methylimidazole-tetraphenyl borate, 1,8-diazabicyclo[5.4.0]undecene-7-tetraphenyl borate, and urethane-based base generators that produce bases upon heating. The content of the curing accelerator in the photosensitive adhesive composition is preferably 0.01-50 parts by mass with respect to 100 parts by mass of the thermosetting resin.

The (C) radiation-polymerizable compound contained in the photosensitive adhesive composition of the invention is preferably an acrylate and/or methacrylate compound. The acrylate and/or methacrylate compound is not particularly restricted, and there may be mentioned methyl acrylate, methyl methacrylate, ethyl acrylate, ethyl methacrylate, butyl acrylate, butyl methacrylate, 2-ethylhexyl acrylate, 2-ethylhexyl methacrylate, pentenyl acrylate, tetrahydrofurfuryl acrylate, tetrahydrofurfuryl methacrylate, diethyleneglycol diacrylate, triethyleneglycol diacrylate, tetraethyleneglycol diacrylate, diethyleneglycol dimethacrylate, triethyleneglycol dimethacrylate, tetraethyleneglycol dimethacrylate, trimethylolpropane diacrylate, trimethylolpropane triacrylate, trimethylolpropane dimethacrylate, trimethylolpropane trimethacrylate, 1,4-butanediol diacrylate, 1,6-hexanediol diacrylate, 1,4-butanediol dimethacrylate, 1,6-hexanediol dimethacrylate, pentaerythritol triacrylate, pentaerythritol tetraacrylate, pentaerythritol trimethacrylate, pentaerythritol tetramethacrylate, dipentaerythritol hexaacrylate, dipentaerythritol hexamethacrylate, styrene, divinylbenzene, 4-vinyltoluene, 4-vinylpyridine, N-vinylpyrrolidone, 2-hydroxyethyl acrylate, 2-hydroxyethyl methacrylate, 1,3-acryloyloxy-2-hydroxypropane, 1,2-methacryloyloxy-2-hydroxypropane, methylenebisacrylamide, N,N-dimethylacrylamide, N-methylolacrylamide, triacrylates of tris(β-hydroxyethyl)isocyanurate, compounds represented by the following formula (13), urethane acrylates or urethane methacrylates, and urea acrylates.

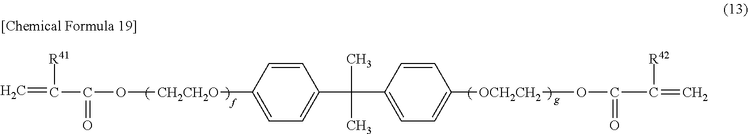

[In the formula, R⁴¹ and R⁴² each independently represent hydrogen or a methyl group, and f and g each independently represent an integer of 1 or greater.]

In addition to these compounds, component (C) may be a radiation-polymerizable copolymer having an ethylenic unsaturated group on a side chain, which is obtained by addition reaction of a compound having at least one ethylenic unsaturated group and a functional group such as an oxirane ring or an isocyanate, hydroxyl or carboxyl group, with a functional group-containing vinyl copolymer.

These radiation-polymerizable compounds may be used alone or in combinations of two or more. Among them, radiation-polymerizable compounds with a glycol skeleton, represented by formula (13) above, are preferred from the standpoint of imparting sufficient alkali-solubility and solvent resistance after curing, and urethane acrylates and methacrylates and isocyanuric acid-modified di/triacrylates and methacrylates are preferred from the standpoint of imparting sufficient high adhesion after curing.

The content of component (C) in the photosensitive adhesive composition of the invention is preferably 20-200 parts by mass and more preferably 30-100 parts by mass with respect to 100 parts by mass of component (A). A content of greater than 200 parts by mass will tend to lower the flow property during heat-fusion due to polymerization, thus reducing the adhesion during thermocompression bonding. On the other hand, a content of less than 20 parts by mass will tend to lower the solvent resistance after the photocuring by exposure, thus interfering with formation of the pattern.

From the viewpoint of preventing electromigration and corrosion of metal conductor circuits, component (C) is preferably a high purity product with a content of not greater than 1000 ppm for impurity ions such as alkali metal ions, alkaline earth metal ions and halide ions, and particularly chloride ion or hydrolyzable chlorine.

From the viewpoint of improving sensitivity, the (D) photoinitiator preferably contains a compound with a molar absorption coefficient of at least 1000 ml/g·cm, and more preferably at least 2000 ml/g·cm, for light with a wavelength of 365 nm. The molar absorption coefficient can be determined by preparing a 0.001% by mass acetonitrile solution of the sample and measuring the absorbance of the solution using a spectrophotometer (“U-3310” (trade name) by Hitachi High-Technologies Corp.).

The 3% weight reduction temperature of the entire photoinitiator mixture in the photosensitive adhesive composition is preferably 200° C. or greater. In order to satisfy this condition, it is necessary to add (D1) a photoinitiator with a 3% weight reduction temperature of 200° C. or greater. The content of component (D1) is not particularly restricted so long as the condition of a 3% weight reduction temperature of 200° C. or greater for the entire photoinitiator mixture can be satisfied, but from the viewpoint of reduced outgas and improved high-temperature adhesion, it is preferably at least 20% by mass, more preferably at least 30% by mass and even more preferably at least 50% by mass of the total photoinitiator mixture. The 3% weight reduction temperature of the photoinitiator is the 3% weight reduction temperature as measured for the sample using a Simultaneous Thermogravimetric Differential Thermal Analyzer (TG/DTA6300 by SII NanoTechnology Inc.) with a temperature-elevating rate of 10° C./min and under a nitrogen flow (400 ml/min).

There are no particular restrictions on such photoinitiators, and as examples there may be mentioned compounds represented by structural formula (1) above, as well as 2,4,6-trimethylbenzoyl-diphenyl-phosphine oxide, 2-benzyl-2-dimethylamino-1-(4-morpholinophenyl)-butanone-1,2-dimethylamino-2-(4-methyl-benzyl)-1-(4-morpholin-4-yl-phenyl)-butan-1-one and 2,4-dimethoxy-1,2-diphenylethan-1-one.

Component (D) preferably contains a compound with a carbazole group. As examples of compounds with carbazole groups there may be mentioned ethanone, 1-[9-ethyl-6-(2-methylbenzoyl)-9H-carbazol-3-yl]-,1-(O-acetyloxime), 3,6-bis-(2-methyl-2 morpholino-propionyl)-9-N-octylcarbazole, 3,6-bis(2-methyl-2-morpholinopropionyl)-9-benzoylcarbazole, 3,6-bis(2-methyl-2-morpholinopropionyl)-9-n-butylcarbazole, 3,6-bis(2-methyl-2-morpholinopropionyl)-9-n-octylcarbazole, 3,6-bis(2-methyl-2-morpholinopropionyl)-9-n-dodecylcarbazole, 2-(N-n-butyl-3′-carbazolyl)-4,6-bis(trichloromethyl)-s-triazine, 2-(N-n-octyl-3′-carbazolyl)-4,6-bis(trichloromethyl)-s-triazine and 2-(N-2″-phenoxyethyl)-3′-carbazolyl)-4,6-bis(trichloromethyl)-s-triazine.

Component (D) preferably contains a compound with an oxime ester group. As examples of compounds with oxime ester groups there may be mentioned 2,4-dimethoxy-1,2-diphenylethan-1-one, 1,2-octanedione, 1-[4-(phenylthio)-,2-(O-benzoyloxime)], ethanone, 1-[9-ethyl-6-(2-methylbenzoyl)-9H-carbazol-3-yl]-,1-(O-acetyloxime), 1-phenyl-1,2-propanedione-2-O-benzoyloxime and 1-phenyl-1,2-propanedione-2-(O-ethoxycarbonyl)oxime.

Component (D) may be used together with another photoinitiator, so long as the 3% weight reduction temperature of the entire photoinitiator mixture in the photosensitive adhesive composition is 200° C. or greater. Such other photoinitiators are not particularly restricted, and bis(2,4,6-trimethylbenzoyl)-phenylphosphine oxide may be mentioned as an example.

When the photosensitive adhesive composition is formed into an adhesive layer with a film thickness of 30 μm or greater, the other photoinitiator is more preferably subjected to bleaching with photoirradiation, from the viewpoint of improving sensitivity and increasing the interior curability. Such other photoinitiators are not particularly restricted, and as examples there may be mentioned compounds that undergo discoloration under UV irradiation, which include benzyl derivatives such as 2-benzyl-2-dimethylamino-1-(4-morpholinophenyl)-butanone-1,2,2-dimethoxy-1,2-diphenylethan-1-one, 1-hydroxy-cyclohexyl-phenyl-ketone, 2-methyl-1-(4-(methylthio)phenyl)-2-morpholinopropanone-1,2,4-diethylthioxanthone and benzyldimethylketal, and bisacylphosphine oxides such as bis(2,6-dimethoxybenzoyl)-2,4,4-trimethyl-pentylphosphine oxide and bis(2,4,6-trimethylbenzoyl)-phenylphosphine oxide. These may be used alone or in combinations of two or more.

When an epoxy resin is used as component (B) in the photosensitive adhesive composition of the invention, a photoinitiator that exhibits a function of promoting polymerization of the epoxy resin under radiation exposure may be included. As examples of photoinitiators that exhibit a function of promoting polymerization of the epoxy resin by irradiation, there may be mentioned photobase generators that generate bases by irradiation, and photoacid generators that generate acids by irradiation.

A photobase generator is preferably also used in the photosensitive adhesive composition of the invention. This can further improve the high-temperature adhesion onto adherends and humidity-resistant reliability of the photosensitive adhesive composition. The reason for this may be that the base generated from the compound acts efficiently as a curing catalyst for epoxy resin, thus further increasing the crosslink density, and that the produced curing catalyst causes less corrosion of boards and the like.

By including a photobase generator in the photosensitive adhesive composition, it is possible to improve the crosslink density and further reduce the outgas during standing at high temperature. The curing process presumably can also be accomplished at a lower temperature and in a shorter time.

Also, if component (A) in the photosensitive adhesive composition has a high content ratio of carboxyl and/or hydroxyl groups, the post-curing moisture absorptivity may be increased and the adhesive force after moisture absorption may be reduced. With the photosensitive adhesive composition described above, however, the presence of a compound that generates a base by exposure to radiation can reduce the carboxyl and/or hydroxyl groups that remain after reaction of the carboxyl and/or hydroxyl groups with the epoxy resin, and thus result in higher levels of both humidity-resistant reliability and adhesion as well as pattern formability.

Any photobase generator that is a compound that generates bases upon irradiation may be used, without any particular restrictions. Strongly basic compounds are preferred as bases to be generated, from the viewpoint of reactivity and curing speed. The pKa value, which is the logarithm of the acid dissociation constant, is generally used as the index of the basicity, and the pKa value of the base is preferably 7 or greater and more preferably 8 or greater in aqueous solution.

As examples of such bases generated by irradiation there may be mentioned imidazole and imidazole derivatives such as 2,4-dimethylimidazole and 1-methylimidazole, piperazine and piperazine derivatives such as 2,5-dimethylpiperazine, piperidine and piperidine derivatives such as 1,2-dimethylpiperidine, proline derivatives, trialkylamine derivatives such as trimethylamine, triethylamine and triethanolamine, pyridine derivatives with amino groups or alkylamino groups substituting at the 4-position, such as 4-methylaminopyridine and 4-dimethylaminopyridine, pyrrolidine and pyrrolidine derivatives such as n-methylpyrrolidine, dihydropyridine derivatives, alicyclic amine derivatives such as triethylenediamine and 1,8-diazabiscyclo(5,4,0)undecene-1 (DBU), and benzylamine derivatives such as benzylmethylamine, benzyldimethylamine and benzyldiethylamine, morpholine derivatives, primary alkylamines, and the like.

As photobase generators that generate such bases by irradiation there may be used, for example, the quaternary ammonium salt derivatives described in Journal of Photopolymer Science and Technology Vol. 12, 313-314 (1999) or Chemistry of Materials Vol. 11, 170-176 (1999). These are optimal for curing of the epoxy resin, in order to produce trialkylamines with high basicity by exposure to active light rays.

As photobase generators, there may be used the carbamic acid derivatives, dimethoxybenzylurethane-based compounds, benzoin-based compounds and orthonitrobenzylurethane compounds mentioned in Journal of American Chemical Society Vol. 118 p. 12925 (1996) or Polymer Journal Vol. 28 p. 795 (1996).

There may also be used oxime derivatives that generate primary amino groups under exposure to active light rays, 2-methyl-1-(4-(methylthio)phenyl)-2-morpholinopropan-1-one (IRGACURE 907 by Ciba Specialty Chemicals, Inc.), 2-benzyl-2-dimethylamino-1-(4-morpholinophenyl)-butanone-1 (IRGACURE 369 by Ciba Specialty Chemicals, Inc.), 3,6-bis-(2-methyl-2-morpholino-propionyl)-9-N-octylcarbazole (OPTOMER N-1414 by ADEKA), which are commercially available as a photoradical generators, hexaarylbisimidazole derivatives (optionally having substituents such as halogens, alkoxy, nitro or cyano on the phenyl groups), benzoisooxazolone derivatives, and the like.

The photobase generator may also employ a compound having a base-generating group introduced on the main chain and/or a side chain of the polymer. The molecular weight in this case is preferably the weight-average molecular weight of 1,000-100,000 and more preferably 5,000-30,000, from the viewpoint of adhesion and flow property as an adhesive.

Since the photobase generator does not exhibit reactivity with the epoxy resin when not exposed to radiation at room temperature, it has highly excellent storage stability at room temperature.

In addition, when these photobase generators are used, the compound is more preferably a compound with the molar absorption coefficient of at least 100 ml/g·cm for light with a wavelength of 365 nm, and the 3% weight reduction temperature of 120° C. or greater, and even more preferably a compound with the molar absorption coefficient of at least 300 ml/g·cm for light with a wavelength of 365 nm, and the 3% weight reduction temperature of 150° C. or greater. The molar absorption coefficient can be determined by preparing a 0.001% by mass acetonitrile solution of the sample and measuring the absorbance of the solution using a spectrophotometer (“U-3310” (trade name) by Hitachi High-Technologies Corp.). The 3% weight reduction temperature of the photoinitiator is the 3% weight reduction temperature as measured for the sample using a Simultaneous Thermogravimetric Differential Thermal Analyzer (TG/DTA6300 by SII NanoTechnology Inc.) with a temperature-elevating rate of 10° C./min and under a nitrogen flow (400 ml/min).

When such photobase generators are used, the photoinitiator content is not particularly restricted but is preferably 0.01-50 parts by mass with respect to 100 parts by mass of component (B).

The photosensitive adhesive composition of the invention may be used with a sensitizing agent if necessary. As examples of sensitizing agents there may be mentioned camphorquinone, benzyl, diacetyl, benzyldimethylketal, benzyldiethylketal, benzyldi(2-methoxyethyl)ketal, 4,4′-dimethylbenzyl-dimethylketal, anthraquinone, 1-chloroanthraquinone, 2-chloroanthraquinone, 1,2-benzanthraquinone, 1-hydroxyanthraquinone, 1-methylanthraquinone, 2-ethylanthraquinone, 1-bromoanthraquinone, thioxanthone, 2-isopropylthioxanthone, 2-nitrothioxanthone, 2-methylthioxanthone, 2,4-dimethylthioxanthone, 2,4-diethylthioxanthone, 2,4-diisopropylthioxanthone, 2-chloro-7-trifluoromethylthioxanthone, thioxanthone-10,10-dioxide, thioxanthone-10-oxide, benzoinmethyl ether, benzomethyl ether, isopropyl ether, benzoinisobutyl ether, benzophenone, bis(4-dimethylaminophenyl)ketone, 4,4′-bisdiethylaminobenzophenone and compounds including azide groups. Any of these may be used alone or two or more may be used in admixture.

A filler may also be used in the photosensitive adhesive composition of the invention, to impart low hygroscopicity and low moisture permeability. As fillers there may be used, for example, metal fillers such as silver powder, gold dust, copper powder and nickel powder, inorganic fillers such as alumina, aluminum hydroxide, magnesium hydroxide, calcium carbonate, magnesium carbonate, calcium silicate, magnesium silicate, calcium oxide, magnesium oxide, aluminum oxide, aluminum nitride, crystalline silica, amorphous silica, boron nitride, titania, glass, iron oxide and ceramics, and organic fillers such as carbon and rubber-based fillers, without any particular restrictions on the type or form.

The filler may be selected for use according to the desired function. For example, a metal filler is added to impart conductivity, thermal conductivity or a thixotropic property to the photosensitive adhesive composition, a non-metal inorganic filler is added to impart thermal conductivity, a low thermal expansion property or low hygroscopicity to the adhesive layer, and an organic filler is added to impart toughness to the adhesive layer. These metal fillers, inorganic fillers or organic fillers may be used alone or in combinations of two or more. Metal fillers, inorganic fillers and insulating fillers are preferred from the viewpoint of imparting conductivity, thermal conductivity, a low moisture absorption property and an insulating property, which are required for semiconductor device adhesive materials, and among inorganic fillers and insulating fillers there are preferred silica fillers and/or alumina fillers from the viewpoint of satisfactory dispersibility in resin varnishes, thixotropy during film formation, and high hot-adhesive-strength.

The filler preferably has the mean particle size of not greater than 10 μm and the maximum particle size of not greater than 30 μm, and more preferably the mean particle size of not greater than 5 μm and the maximum particle size of not greater than 20 μm. If the mean particle size exceeds 10 μm and the maximum particle size exceeds 30 μm, it may be difficult to obtain an effect of improved fracture toughness. The lower limits are not particularly restricted but will normally be 0.001 μm for both.

The filler preferably satisfies both the mean particle size of not greater than 10 μm and the maximum particle size of not greater than 30 μm. If the filler with the maximum particle size of not greater than 30 μm but the mean particle size exceeding 10 μm is used, it will tend to be difficult to obtain the high adhesive strength. If the filler with the mean particle size of not greater than 10 μm but the maximum particle size exceeding 30 μm is used, the grain size distribution will be widened and there will tend to be variation in the adhesive strength, while the surface will also tend to be roughened, lowering the adhesive force, when the photosensitive adhesive composition is worked into a thin-film.

The method for measuring the mean particle size and maximum particle size of the filler may be a method whereby the particle sizes of about filler particles are measured using a scanning electron microscope (SEM). As an example of measurement using SEM, there may be mentioned a method in which a sample is prepared by using the adhesive layer to bond the semiconductor element and the supporting member for mounting a semiconductor and then heat curing it (preferably at 150-180° C. for 1-10 hours), and the center section of the sample is cut for observation of the cross-section by SEM. Here, the proportion of filler particles with particle sizes of 30 μm or less is preferably at least 80% of the total filler.

The filler content in the photosensitive adhesive composition of the invention may be determined according to the properties and function to be imparted, but it is preferably 1-50% by mass, more preferably 2-40% by mass and even more preferably 5-30% by mass with respect to the total of the resin component and filler. Increasing the amount of filler can achieve the high elastic modulus and effectively improve the dicing property (cuttability with a dicer blade), wire bonding property (ultrasonic wave efficiency) and hot-adhesive-strength. If the filler is increased above the necessary amount the thermocompression bonding property will tend to be impaired, and therefore the filler content is preferably limited to within the range specified above. The optimal filler content is determined for the desired balance of properties. In cases where a filler is used, mixing and kneading may be accomplished using an appropriate combination of dispersers such as an ordinary stirrer, kneader, triple roll, ball mill or the like.

Various coupling agents may also be added to the photosensitive adhesive composition of the invention to improve the interfacial bonding between different types of materials. As examples of coupling agents there may be mentioned silane-based, titanium-based and aluminum-based agents, among which silane-based coupling agents are preferred for a greater effect. The amount of the coupling agent used is preferably 0.01-20 parts by mass with respect to 100 parts by mass of component (A) that is used, from the standpoint of the effect, heat resistance and cost.

An ion scavenger may also be added to the photosensitive adhesive composition of the invention to adsorb ionic impurities and improve the insulating reliability when wet. Such an ion scavenger is not particularly restricted, and as examples there may be mentioned compounds known as copper inhibitors to prevent ionization and dissolution of copper, such as triazinethiol compounds and phenol-based reducing agents, as well as inorganic compounds such as powdered bismuth-based, antimony-based, magnesium-based, aluminum-based, zirconium-based, calcium-based, titanium-based and tin-based compounds, as well as mixtures of the same. Specific examples include, but are not restricted to, inorganic ion scavengers by Toagosei Co., Ltd. under the trade names of IXE-300 (antimony-based), IXE-500 (bismuth-based), IXE-600 (antimony/bismuth mixture-based), IXE-700 (magnesium/aluminum mixture-based), IXE-800 (zirconium-based) and IXE-1100 (calcium-based). Any of these may be used alone or in mixtures of two or more. The amount of the ion scavenger used is preferably 0.01-10 parts by mass with respect to 100 parts by mass of component (A), from the viewpoint of effect of the addition, heat resistance, and cost.

Antioxidants may also be added to the photosensitive adhesive composition of the invention, for the purpose of increasing storage stability, preventing electromigration, and preventing corrosion of metal conductor circuits. Such antioxidants are not particularly restricted, and as examples there may be mentioned benzophenone-based, benzoate-based, hindered amine-based, benzotriazole-based and phenol-based antioxidants. The amount of the antioxidant used is preferably 0.01-10 parts by mass with respect to 100 parts by mass of component (A), from the viewpoint of effect of the addition, heat resistance, and cost.

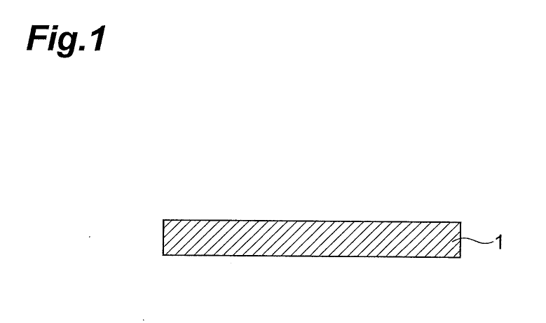

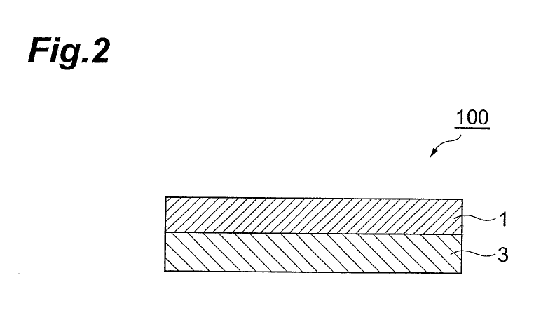

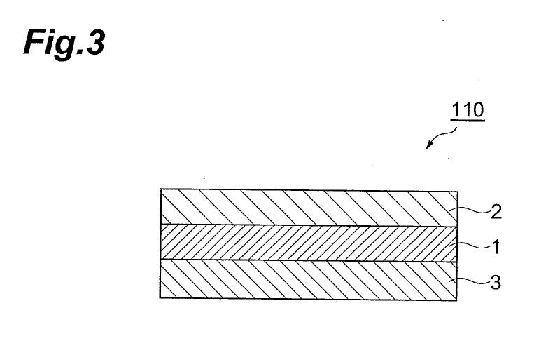

FIG. 1 is a schematic cross-sectional view showing an embodiment of a film-like adhesive according to the invention. The film-like adhesive (adhesive film) 1 shown in FIG. 1 is obtained by forming a film from the photosensitive adhesive composition. FIG. 2 is a schematic cross-sectional view showing an embodiment of an adhesive sheet according to the invention. The adhesive sheet 100 shown in FIG. 2 is constructed of a base 3, and an adhesive layer composed of a film-like adhesive 1 formed on one side of the base. FIG. 3 is a schematic cross-sectional view showing another embodiment of an adhesive sheet of the invention. The adhesive sheet 110 shown in FIG. 3 is constructed of a base 3, and an adhesive layer composed of a film-like adhesive 1, and a cover film 2, formed on one side of the base.

The film-like adhesive 1 can be obtained by a method in which the (A) resin with a carboxyl and/or hydroxyl group, (B) thermosetting resin, (C) radiation-polymerizable compound and (D) photoinitiator, as well as other components added as necessary, are combined in an organic solvent and the mixture is kneaded to prepare a varnish, a varnish layer is formed on the base 3, and the varnish layer is dried by heating and the base 3 is subsequently removed. They may also be stored and used as adhesive sheets 100, 110, without removal of the base 3.

The mixing and kneading can be accomplished using an appropriate combination of dispersers such as an ordinary stirrer, kneader, triple roll or ball mill. Drying is carried out at a temperature so that the (B) thermosetting resin does not completely react during drying, and under conditions in which the solvent thoroughly volatilizes. Specifically, the varnish layer is dried by heating, usually at 60-180° C. for 0.1-90 minutes. The preferred thickness of the varnish layer before drying is 1-100 μm. The thickness of less than 1 μm will tend to impair the adhesive anchoring function, while the thickness of greater than 100 μm will tend to increase the residual volatile components described hereunder.

The preferred residual volatile component of the obtained varnish layer is not greater than 10% by mass. The residual volatile component of greater than 10% by mass will tend to leave voids inside the adhesive layer due to foam produced by volatilization of the solvent during assembly heating and will tend to impair the humidity-resistant reliability, while also increasing the potential for contamination of the surrounding material or members due to volatilizing components generated during heating. The conditions for measuring the residual volatilizing components are as follows. Specifically, the value for the film-like adhesive cut to a size of 50 mm×50 mm was measured using [(M2−M1)/M1]×100=residual volatile component (%), where M1 is the initial mass and M2 is the mass after heating the film-like adhesive for 3 hours in an oven at 160° C.

The temperature at which the thermosetting resin does not completely react is, specifically, a temperature below the peak temperature for heat of reaction, with measurement using a DSC (for example, a “Model DSC-7” (trade name) by Perkin-Elmer), with a sample mass of 10 mg, a temperature-elevating rate of 5° C./min and a measuring atmosphere of air.

The organic solvent used to prepare the varnish, i.e. the varnish solvent, is not particularly restricted so long as it can uniformly dissolve or disperse the material. As examples there may be mentioned dimethylformamide, toluene, benzene, xylene, methyl ethyl ketone, tetrahydrofuran, ethylcellosolve, ethylcellosolve acetate, dioxane, cyclohexanone, ethyl acetate and N-methyl-pyrrolidinone.

The base 3 is not particularly restricted so long as it can withstand the drying conditions. For example, a polyester film, polypropylene film, polyethylene terephthalate film, polyimide film, polyetherimide film, polyether naphthalate film or methylpentene film may be used as the base 3. The film used as the base 3 may also be a multilayer film comprising a combination of two or more different types, and the surface may be treated with a silicone-based or silica-based release agent.

The film-like adhesive 1 of the invention may be laminated with a dicing sheet to form an adhesive sheet. The dicing sheet is a sheet comprising an adhesive layer formed on a base, and the adhesive layer may be a pressure-sensitive type or radiation-curing type. The base is preferably an expandable base. Using such an adhesive sheet, it is possible to obtain an integrated dicing/die bond adhesive sheet having a function as a die bond film and also having a function as a dicing sheet.

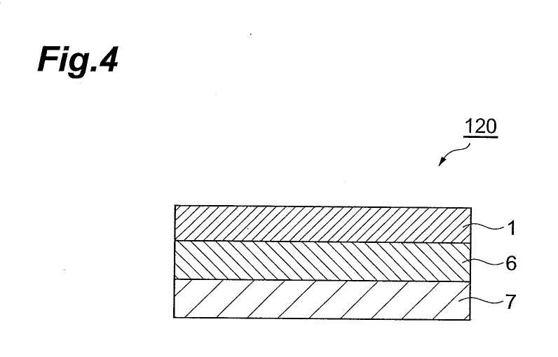

Specifically, the integrated dicing/die bond adhesive sheet may be an adhesive sheet 120 such as shown in FIG. 4, having a base film 7, an adhesive layer 6 and a film-like adhesive 1 of the invention formed in that order.

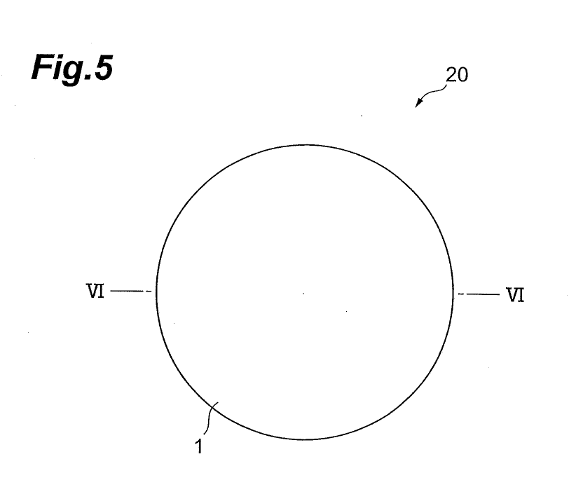

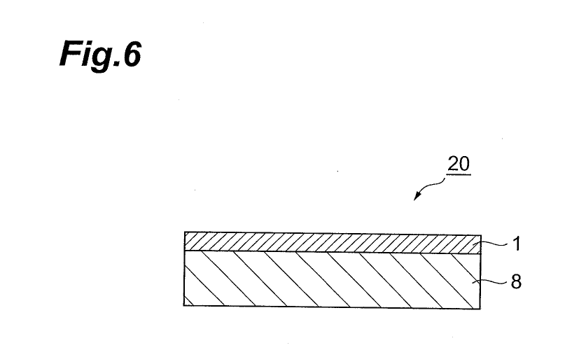

FIG. 5 is a top view showing an embodiment of a semiconductor wafer with an adhesive layer according to the invention, and FIG. 6 is an end view along line VI-VI in FIG. 5. The semiconductor wafer with an adhesive layer 20 shown in FIGS. 5 and 6 comprises a semiconductor wafer 8, and a film-like adhesive (adhesive layer) 1 composed of the aforementioned photosensitive adhesive composition, formed on one side thereof.

The semiconductor wafer with an adhesive layer 20 is obtained by laminating the film-like adhesive 1 on the semiconductor wafer 8 while heating. Since the film-like adhesive 1 is a film composed of the aforementioned photosensitive adhesive composition, it can be attached to the semiconductor wafer 8 at low temperatures of, for example, room temperature (25° C.) to about 150° C.

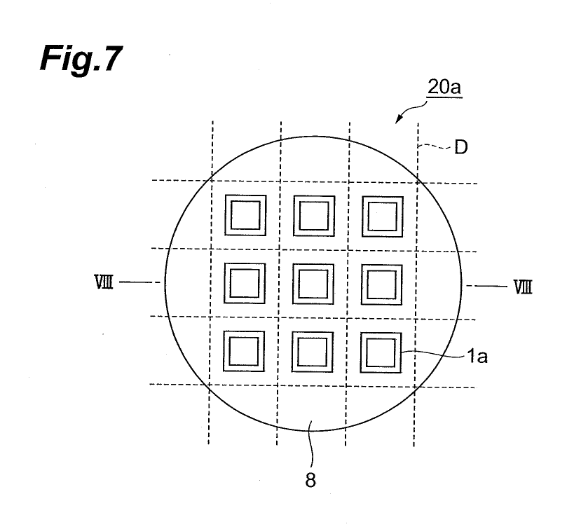

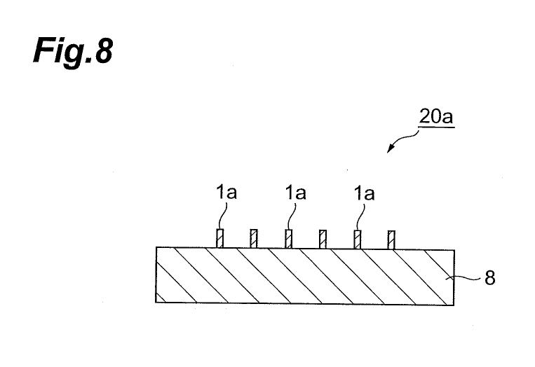

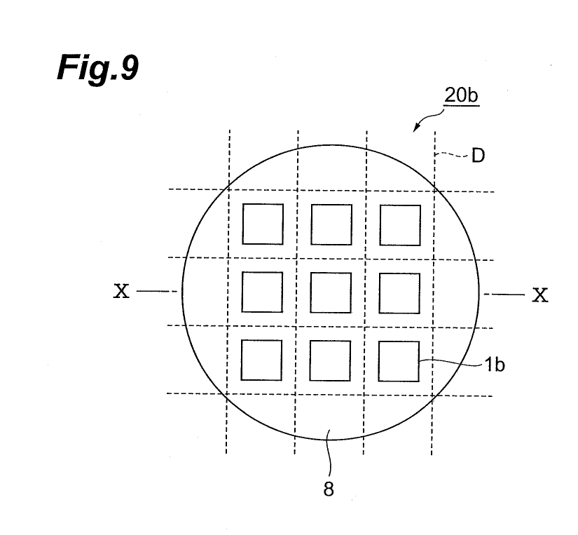

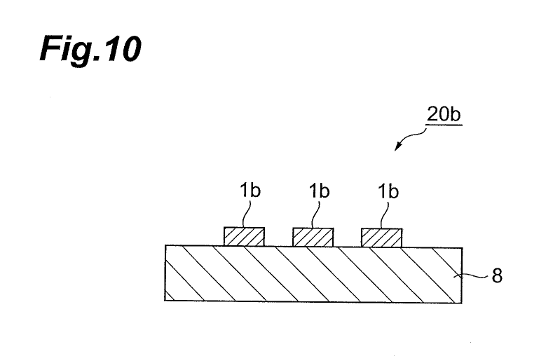

FIG. 7 and FIG. 9 are top views showing embodiments of an adhesive pattern according to the invention, FIG. 8 is an end view along line VIII-VIII in FIG. 7, and FIG. 10 is an end view along line X-X in FIG. 9. The adhesive patterns 1a and 1b shown in FIGS. 7, 8, 9 and 10 are formed on the semiconductor wafer 8 as the adherend, so as to form patterns along roughly square sides, or square patterns.

The adhesive patterns 1a and 1b are formed by forming the film-like adhesive 1 composed of a photosensitive adhesive composition on the semiconductor wafer 8 as the adherend to obtain a semiconductor wafer with an adhesive layer 20, exposing the film-like adhesive 1 through a photomask, and developing the exposed film-like adhesive 1 with an alkali developing solution. This will yield semiconductor wafers with adhesive layers 20a, 20b on which adhesive patterns 1a, 1b have been formed.

The use of the film-like adhesive of the invention will now be explained in detail, with reference to the drawings of semiconductor devices comprising film-like adhesives. Incidentally, semiconductor devices with various structures have been proposed in recent years, and use of the film-like adhesive of the invention is not limited to semiconductor devices having the structures described below.

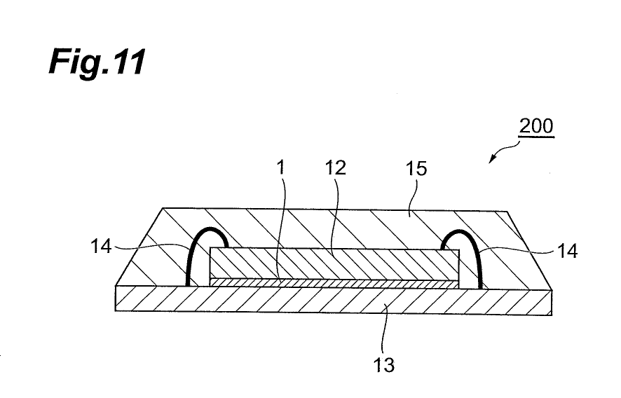

FIG. 11 is a schematic cross-sectional view showing an embodiment of a semiconductor device according to the invention. In the semiconductor device 200 shown in FIG. 11, the semiconductor element 12 is bonded to the supporting member for mounting a semiconductor element 13 via the film-like adhesive 1 of the invention, and the connecting terminals (not shown) of the semiconductor element 12 are electrically connected to the external connecting terminals (not shown) via wires 14, and sealed with a sealing material 15.

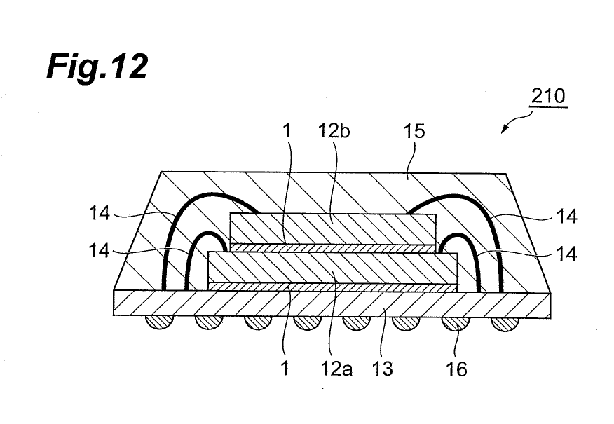

FIG. 12 is a schematic cross-sectional view showing another embodiment of a semiconductor device according to the invention. In the semiconductor device 210 shown in FIG. 12, the first-level semiconductor element 12a is bonded to the supporting member for mounting a semiconductor element 13 on which terminals 16 have been formed, via a film-like adhesive 1 of the invention, and the second-level semiconductor element 12b is bonded on the first-level semiconductor element 12a also via a film-like adhesive 1 of the invention. The connecting terminals (not shown) of the first-level semiconductor element 12a and second-level semiconductor element 12b are electrically connected with external connecting terminals via wires 14, and are sealed with a sealing material 15. Thus, the film-like adhesive of the invention may be suitably used in a semiconductor device having a construction with a plurality of layered semiconductor elements.

The semiconductor devices (semiconductor packages) 200, 210 shown in FIG. 11 and FIG. 12 can be obtained, for example, by dicing the semiconductor wafer with adhesive layer 20b shown in FIG. 9 along the dotted lines D, thermocompression bonding the diced semiconductor element with the film-like adhesive onto the supporting member for mounting a semiconductor element 13 to bond them, and then passing it through a wire bonding step, and if necessary also a sealing step with a sealing material. The heating temperature for thermocompression bonding is normally 20-250° C., the load is normally 0.01-20 kgf and the heating time is normally 0.1-300 seconds.

### EXAMPLES

The present invention will now be explained in greater detail based on examples and comparative examples, with the understanding that the invention is in no way limited to the examples.

(Synthesis of Polyimide PI-1)

In a flask equipped with a stirrer, thermometer, condenser tube and nitrogen substitution device there were charged 1.89 g of 3,5-diaminobenzoic acid (molecular weight: 152.2, hereunder abbreviated as “DABA”), 15.21 g of aliphatic etherdiamine (“D-400” (trade name) by BASF, molecular weight: 452.4), 0.39 g of 1,1,3,3-tetramethyl-1,3-bis(4-aminophenyl)disiloxane (“LP-7100” (trade name) of Shin-Etsu Chemical Co., Ltd., molecular weight: 248.5) and 116 g of N-methyl-2-pyrrolidinone (hereunder abbreviated as “NMP”).

Next, 16.88 g of 4,4′-oxydiphthalic dianhydride (molecular weight: 326.3, hereunder abbreviated as “ODPA”) was added to the flask in small portions at a time while cooling the flask in an ice bath. Upon completion of the addition, the mixture was further stirred at room temperature (25° C.) for 5 hours.

A moisture receptor-equipped reflux condenser was then mounted on the flask, 70 g of xylene was added, and the temperature was increased to 180° C. while blowing in nitrogen gas to maintain the temperature for 5 hours, and the xylene was azeotropically removed with the water. The obtained solution was cooled to room temperature and then poured into distilled water for reprecipitation. The obtained precipitate was dried with a vacuum dryer to obtain a polyimide resin (hereunder referred to as “polyimide PI-1”). GPC measurement of the obtained polyimide resin resulted in Mw=33000 based on polystyrene. The Tg of the obtained polyimide resin was 55° C.

(Synthesis of Polyimide PI-2)

In a flask equipped with a stirrer, thermometer and nitrogen substitution device there were charged 2.16 g of 5,5′-methylene-bis(anthranilic acid) (molecular weight: 286.3, hereunder abbreviated as “MBAA”), 15.13 g of aliphatic etherdiamine (“D-400”), 1.63 g of 1,1,3,3-tetramethyl-1,3-bis(4-aminophenyl)disiloxane (“LP-7100”) and 115 g of NMP.

Next, 16.51 g of ODPA was added to the flask in small portions at a time while cooling the flask in an ice bath. Upon completion of the addition, the mixture was further stirred at room temperature for 5 hours. A moisture receptor-equipped reflux condenser was then mounted on the flask, 81 g of xylene was added, the temperature was increased to 180° C. while blowing in nitrogen gas to maintain the temperature for 5 hours, and the xylene was azeotropically removed with the water. The obtained solution was cooled to room temperature and then poured into distilled water for reprecipitation, to obtain a polyimide resin (hereunder referred to as “polyimide PI-2”). GPC measurement of the obtained polyimide resin resulted in Mw=30000 based on polystyrene. The Tg of the obtained polyimide resin was 31° C.

(Synthesis of Polyimide PI-3)

In a flask equipped with a stirrer, thermometer and nitrogen substitution device there were charged 20.5 g of 2,2-bis(4-(4-aminophenoxy)phenyl)propane (molecular weight: 410.5, hereunder abbreviated as “BAPP”) and 101 g of NMP.

Next, 20.5 g of 1,2-(ethylene)bis(trimellitate anhydride) (molecular weight: 410.3, hereunder abbreviated as “EBTA”) was added to the flask in small portions at a time while cooling the flask in an ice bath. Upon completion of the addition, the mixture was further stirred at room temperature for 5 hours. A moisture receptor-equipped reflux condenser was then mounted on the flask, 67 g of xylene was added, the temperature was increased to 180° C. while blowing in nitrogen gas to maintain the temperature for 5 hours, and the xylene was azeotropically removed with the water. The obtained solution was cooled to room temperature and then poured into distilled water for reprecipitation, to obtain a polyimide resin (hereunder referred to as “polyimide PI-3”). GPC measurement of the obtained polyimide resin resulted in Mw=98000 based on polystyrene. The Tg of the obtained polyimide resin was 180° C.

The polyimides PI-1 to −3 were used for mixing of the components in the compositional ratio (units:parts by mass) listed in Tables 1 and 2 below, to obtain photosensitive adhesive compositions (adhesive layer-forming varnishes).

The symbols for the components in Tables 1 and 2 have the following meanings.

BPE-100: Ethoxylated bisphenol A dimethacrylate by Shin-Nakamura Chemical Co., Ltd.
M-313: Isocyanuric acid EO-modified tri/diacrylate by Toagosei Co., Ltd.
VG-3101: Trifunctional epoxy resin by Printec.
BEO-60E: Bisphenol A bis(triethyleneglycolglycidyl ether) by New Japan Chemical Co., Ltd.
TrisP-PA: Trisphenol compound (α,α′,α″-tris(4-hydroxyphenyl)-1-ethyl-4-isopropylbenzene) by Honshu Chemical Industry Co., Ltd.
R972: Hydrophobic fumed silica (mean particle size: approximately 16 nm) by Nippon Aerosil Co., Ltd.
I-OXE01: 2,4-Dimethoxy-1,2-diphenylethan-1-one, 1,2-octanedione, 1-[4-(phenylthio)-,2-(O-benzoyloxime)], oxime ester group-containing compound (3% weight reduction temperature: 210° C., molar absorption coefficient at 365 nm: 7000 ml/g·cm) by Ciba Specialty Chemicals Co., Ltd.
I-OXE02: Ethanone, 1-[9-ethyl-6-(2-methylbenzoyl)-9H-carbazol-3-yl]-,1-(O-acetyloxime), carbazole and oxime ester group-containing compound (3% weight reduction temperature: 365° C., molar absorption coefficient at 365 nm: 7700 ml/g·cm) by Ciba Specialty Chemicals Co., Ltd.
N-1919: Non-disclosed structure, oxime ester group-containing compound (3% weight reduction temperature: 270° C., molar absorption coefficient at 365 nm: 4500 ml/g·cm) by Adeka Corp.
N-1414: 3,6-bis-(2-Methyl-2-morpholino-propionyl)-9-N-octylcarbazole, carbazole group-containing compound (3% weight reduction temperature: 370° C., molar absorption coefficient at 365 nm: 2000 ml/g·cm) by Adeka Corp.
D-1173: 2-Hydroxy-2-methyl-1-phenyl-propan-1-one (3% weight reduction temperature: 90° C., molar absorption coefficient at 365 nm: 50 ml/g·cm) by Ciba Specialty Chemicals Co., Ltd.
I-651: 2,2-Dimethoxy-1,2-diphenylethan-1-one (3% weight reduction temperature: 140° C., molar absorption coefficient at 365 nm: 350 ml/g·cm) by Ciba Specialty Chemicals Co., Ltd.
I-819: bis(2,4,6-Trimethylbenzoyl)-phenylphosphine oxide (3% weight reduction temperature: 190° C., molar absorption coefficient at 365 nm: 2300 ml/g·cm) by Ciba Specialty Chemicals Co., Ltd.
D-TPO: 2,4,6-Trimethylbenzoyl-diphenyl-phosphine oxide (3% weight reduction temperature: 230° C., molar absorption coefficient at 365 nm: 400 ml/g·cm) by Ciba Specialty Chemicals Co., Ltd.
I-379EG: 2-Dimethylamino-2-(4-methyl-benzyl)-1-(4-morpholin-4-yl-phenyl)-butan-1-one (3% weight reduction temperature: 230° C., molar absorption coefficient at 365 nm: 7000 ml/g·cm) by Ciba Specialty Chemicals Co., Ltd.
NMP: N-methyl-2-pyrrolidinone by Kanto Kagaku Co., Ltd.

The 3% weight reduction temperature is the value measured using a Simultaneous Thermogravimetric Differential Thermal Analyzer (“TG/DTA 6300” (trade name) by SII NanoTechnology Inc.), under conditions with a nitrogen flow of 400 ml/min.

Each of the obtained adhesive layer-forming varnishes was coated onto a base (release agent-treated PET film) to a post-drying thickness of 40 μm, and then heated in an oven at 80° C. for 20 minutes and then at 120° C. for 20 minutes to obtain adhesive sheets for Examples 1-8 and Comparative Examples 1-5 having adhesive layers formed on bases.

<Evaluation of Low-Temperature Attachment Property>

Each of the adhesive sheets obtained in Examples 1-8 and Comparative Examples 1-5 was laminated onto the back side of a silicon wafer (6-inch diameter, 400 μm thickness) placed on a support stage (the side opposite the support stage side), by orienting the adhesive layer to the silicon wafer side and pressing with a roll (temperature: 100° C., linear pressure: 4 kgf/cm, feed rate: 0.5 m/min). Next, the base (PET film) was peeled off and an 80 μm-thick, 10 mm-wide, 40 mm-long polyimide film (UPILEX, trade name of Ube Industries, Ltd.) was pressed onto the adhesive layer with a roll under the same conditions described above for lamination. Each sample prepared in this manner was subjected to a 90° peel test at room temperature using a rheometer (STROGRAPH E-S (trade name) by Toyo Seiki Laboratories), for measurement of the adhesive layer-UPILEX peel strength. Samples with a peel strength of 2 N/cm or greater were evaluated as A, and samples with less than 2 N/cm were evaluated as B, based on the measurement results. The results are shown in Tables 1 and 2.

<Evaluation of Pattern Formability>

Each of the adhesive sheets of Examples 1-8 and Comparative Examples 2-5 was laminated onto a silicon wafer (6-inch diameter, 400 μm thickness) at a temperature of 100° C. while the adhesive sheet of Comparative Example 1 was laminated at a temperature of 300° C., by orienting the adhesive layer to the silicon wafer side and pressing with a roll (linear pressure: 4 kgf/cm, feed rate: 0.5 m/min).

Next, a negative pattern mask (“No. G-2” (trade name) by Hitachi Chemical Co., Ltd.) was placed on the base (PET film) and exposed at 500 mJ/cm² with a high precision parallel exposure apparatus (“EXM-1172-B-∞ (trade name) by Orc Manufacturing Co., Ltd.), and allowed to stand for approximately 30 seconds on a hot plate at 80° C.

The base (PET film) was then removed, and a conveyor developing machine (Yako Co., Ltd.) was used for spray development with a 2.38% by mass solution of tetramethylammonium hydride (TMAH) as the developing solution, a temperature of 28° C. and a spray pressure of 0.18 MPa, after which it was washed with purified water at a temperature of 23° C. and a spray pressure of 0.02 MPa. After development, it was visually confirmed whether a pattern with line width/space width=400 μm/400 μm had been formed, and an evaluation of A was assigned for pattern formation while B was assigned for no pattern formation. The results are shown in Tables 1 and 2.

<Evaluation of Sensitivity>

Each of the adhesive sheets of Examples 1-8 and Comparative Examples 2-5 was laminated onto a silicon wafer (6-inch diameter, 400 μm thickness) at a temperature of 100° C. while the adhesive sheet of Comparative Example 1 was laminated at a temperature of 300° C., by orienting the adhesive layer to the silicon wafer side and pressing with a roll (linear pressure: 4 kgf/cm, feed rate: 0.5 m/min).

Next, a photomask (PHOTOTECH 41 step density tablet (trade name) by Hitachi Chemical Co., Ltd.), commonly known as a step tablet, was placed on the base (PET film) as a negative pattern photomask, in such a manner for decreasing light transmittance in a stepwise manner, and exposed at 500 mJ/cm² with a high precision parallel exposure apparatus (“EXM-1172-B-∞” (trade name) by Orc Manufacturing Co., Ltd.), and then allowed to stand on a hot plate at 80° C. for approximately 30 seconds.

The base (PET film) was then removed, and a conveyor developing machine (Yako Co., Ltd.) was used for spray development with a 2.38% by mass solution of tetramethylammonium hydride (TMAH) as the developing solution, a temperature of 28° C. and a spray pressure of 0.18 MPa, after which it was washed with purified water at a temperature of 23° C. and a spray pressure of 0.02 MPa. After development, the number of steps of the step tablet of the photocured film formed on the silicon wafer was counted to evaluate the photosensitivity of the adhesive sheet. The number of remaining steps was evaluated based on these measurement results. The results are shown in Tables 1 and 2.

<Measurement of 260° C. Peel Strength (Evaluation of Adhesion at High Temperature)>

A silicon wafer (6-inch diameter, 400 μm thickness) was half-cut to a depth of 180 μm with size of 5 mm×5 mm. Next, each of the adhesive sheets of Examples 1-8 and Comparative Examples 2-5 was laminated onto a half-cut silicon wafer at a temperature of 100° C. while the adhesive sheet of Comparative Example 1 was laminated at a temperature of 300° C., by orienting the adhesive layer to the silicon wafer side and pressing with a roll (linear pressure: 4 kgf/cm, feed rate: 0.5 m/min). The obtained sample was exposed at 500 mJ/cm² with a high precision parallel exposure apparatus (“EXM-1172-B-∞ (trade name) by Orc Manufacturing Co., Ltd.), and allowed to stand for approximately 30 seconds on a hot plate at 80° C. The base (PET film) was then removed and the sample was individuated to 5 mm×5 mm.

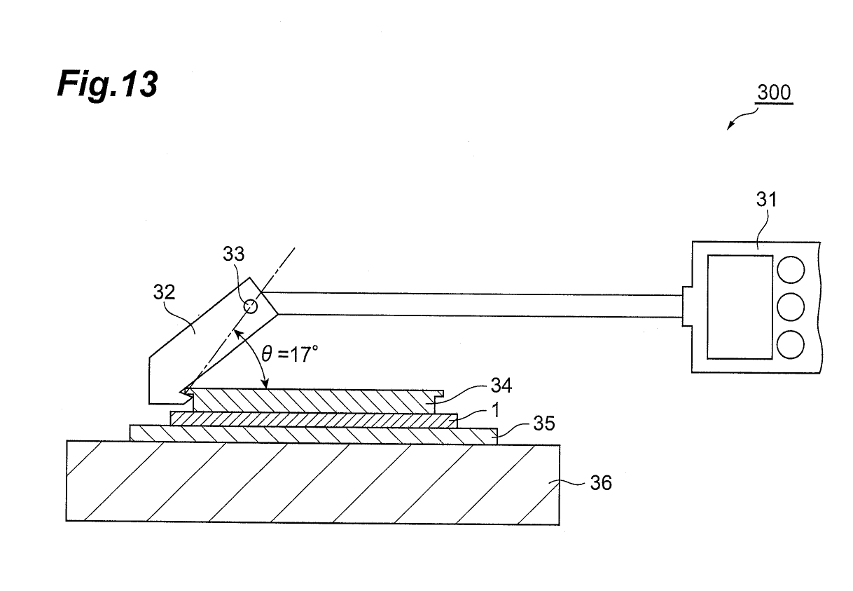

The silicon wafer with the individuated adhesive layer was mounted on a glass substrate (10 mm×10 mm×0.55 mm) with the adhesive layer oriented toward the glass substrate side and pressed at 2 kgf, while contact bonding each of the adhesive sheets of Examples 1-8 and Comparative Examples 2-5 at a temperature of 150° C. and the adhesive sheet of Comparative Example 1 at a temperature of 300° C., for 10 seconds. The obtained test piece was heat cured in an oven at 120° C. for 3 hours. Curing was performed at 180° C. for 1 hour for Comparative Example 1. Next, the test piece was heated on a heating plate at 260° C. for 10 seconds, and the peel strength tester shown in FIG. 13 was used to measure the peel strength of the silicon wafer at 260° C. with a measuring speed of 0.5 mm/sec, with the value being recorded as the 260° C. peel strength. The results are shown in Tables 1 and 2.

In the peel strength tester 300 shown in FIG. 13, a handle 32 is provided, at a variable angle around a fulcrum 33, at the end of a rod mounted on a push-pull gauge 31. Measurement of the 260° C. peel strength was accomplished by placing the test piece, comprising a silicon wafer 34 with a protrusion and a glass substrate 35 bonded via a film-like adhesive 1, on a heating plate 36 at 260° C. and, with the handle 32 engaged with the protrusion of the silicon wafer 34, using the push-pull gauge 31 to measure the peel stress when the handle 32 was moved at 0.5 mm/sec.

<Measurement of 3% Weight Reduction Temperature of Adhesive Layer>

Each of the adhesive sheets of Examples 1-8 and Comparative Examples 2-5 was laminated onto a silicon wafer (6-inch diameter, 400 μm thickness) at a temperature of 100° C. while the adhesive sheet of Comparative Example 1 was laminated at a temperature of 300° C., by orienting the adhesive layer to the silicon wafer side and pressing with a roll (linear pressure: 4 kgf/cm, feed rate: 0.5 m/min).

The obtained sample was exposed at 500 mJ/cm² with a high precision parallel exposure apparatus (“EXM-1172-B-∞, trade name of Orc Manufacturing Co., Ltd.), and allowed to stand for approximately 30 seconds on a hot plate at 80° C. The base (PET film) was then removed, and after heat curing in an oven under conditions of 120° C., 3 hours, the adhesive layer on the silicon wafer was shaved off and a Simultaneous Thermogravimetric Differential Thermal Analyzer (“TG/DTA6300”, trade name of SII NanoTechnology Inc.) was used to measure the 3% weight reduction temperature under a nitrogen flow (400 ml/min). The results are shown in Tables 1 and 2.

TABLE 1

| item | | | Example 1 | Example 2 | Example 3 | Example 4 | Example 5 | Example 6 | Example 7 | Example 8 |
|---|---|---|---|---|---|---|---|---|---|---|
| Film | Polyimide | | PI-1 | PI-2 | PI-2 | P1-2 | PI-1 | PI-1 | PI-1 | PI-1 |
| composition | (100 parts by mass) | | | | | | | | | |
| | Radiation-polymerizable | BPE-100 | 40 | 40 | 40 | 40 | 40 | 40 | 40 | 40 |
| | compound | M-313 | 30 | 30 | 30 | 30 | 30 | 30 | 30 | 30 |
| | Epoxy resin | VG-3101 | 5 | 5 | 5 | 5 | 5 | 5 | 5 | 5 |
| | | BEO-60E | 10 | 10 | 10 | 10 | 10 | 10 | 10 | 10 |
| | Curing agent | TrisP-PA | 5 | 5 | 5 | 5 | 5 | 5 | 5 | 5 |
| | Filler | R-972 | 5 | 5 | 5 | 5 | 5 | 5 | 5 | 5 |
| | Photoinitiator | I-OXE01 | — | — | — | — | 1 | — | — | — |
| | | I-OXE02 | 3 | — | — | 1 | — | — | — | — |
| | | D-TPO | — | 5 | — | — | — | — | — | — |
| | | I-819 | — | — | 2 | 2 | 2 | — | 2 | — |
| | | I-379EG | — | — | 1 | — | — | — | — | — |
| | | N-1919 | — | — | — | — | — | 3 | — | — |
| | | N-1414 | — | — | — | — | — | — | 1 | 3 |
| | Coating solvent | NMP | 200 | 210 | 210 | 210 | 200 | 200 | 200 | 200 |

| | | | | | | | | |
|---|---|---|---|---|---|---|---|---|
| 3% Weight-reduction temperature of entire | 365 | 230 | 210 | 250 | 205 | 270 | 250 | 370 |
| photoinitiator mixture (° C.) | | | | | | | | |
| Low-temperature attachment property | A | A | A | A | A | A | A | A |
| Pattern formability | A | A | A | A | A | A | A | A |
| Sensitivity (x/41) | 41 | 6 | 12 | 30 | 28 | 23 | 19 | 19 |
| 260° C. Peel strength (MPa) | 0.6 | 0.4 | 0.4 | 0.6 | 0.5 | 0.6 | 0.7 | 0.7 |
| 3% Weight reduction temperature of adhesive | 370 | 275 | 300 | 350 | 290 | 320 | 350 | 370 |
| layer (° C.) | | | | | | | | |

TABLE 2

| item | | | Comp. Ex. 1 | Comp. Ex. 2 | Comp. Ex. 3 | Comp. Ex. 4 | Comp. Ex. 5 |
|---|---|---|---|---|---|---|---|
| Film | Polyimide (100 parts by mass) | | PI-3 | PI-2 | PI-2 | PI-1 | PI-1 |
| composition | Radiation-polymerizable | BPE-100 | 40 | 40 | 40 | 40 | 40 |
| | compound | M-313 | 30 | 30 | 30 | 30 | 30 |
| | Epoxy resin | VG-3101 | 5 | 5 | 5 | 5 | 5 |
| | | BEO-60E | 10 | 10 | 10 | 10 | 10 |
| | Curing agent | TrisP-PA | 5 | 5 | 5 | 5 | 5 |
| | Filler | R-972 | 5 | 5 | 5 | 5 | 5 |
| | Photoinitiator | I-OXE02 | 3 | — | — | 0.5 | — |
| | | I-651 | — | 3 | — | 4 | — |
| | | I-819 | — | — | — | — | 5 |
| | | D-1173 | — | — | 3 | — | — |
| | Coating solvent | NMP | 270 | 210 | 210 | 200 | 200 |

| | | | | | |
|---|---|---|---|---|---|
| 3% Weight-reduction temperature of entire | 365 | 140 | 90 | 140 | 190 |
| photoinitiator mixture (° C.) | | | | | |
| Low-temperature attachment property | B | A | B* | A | A |
| Pattern formability | B | A | B* | A | A |
| Sensitivity (x/41) | — | 7 | — | 12 | 17 |
| 260° C. Peel strength (MPa) | 1.5 | 0.05 | 0.01 | 0.02 | 0.2 |
| 3% Weight reduction temperature of adhesive | 380 | 180 | 120 | 180 | 220 |
| layer (° C.) | | | | | |

*Upon heat drying during coating, the photoinitiator decomposed and the acrylate polymerized, and therefore the low-temperature attachment property and pattern formability were evaluated as B.

1. A photosensitive adhesive composition comprising:
(A) a resin with a carboxyl and/or hydroxyl group,
(B) a thermosetting resin,
(C) a radiation-polymerizable compound, and
(D) a photoinitiator,
wherein a 3% weight reduction temperature of an entirety of the photoinitiator in the composition is 200° C. or greater.

2. The photosensitive adhesive composition according to claim 1, wherein the (D) photoinitiator contains a compound having a molar absorption coefficient of 1000 ml/g·cm or greater for light with a wavelength of 365 nm.

3. The photosensitive adhesive composition according to claim 1, wherein the (D) photoinitiator contains a compound with a carbazole group.

4. The photosensitive adhesive composition according to claim 1, wherein the (D) photoinitiator contains a compound with an oxime ester group.

5. The photosensitive adhesive composition according to claim 1, wherein the (D) photoinitiator contains a compound represented by the following structural formula (1):

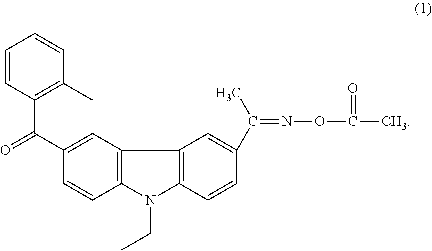

6. The photosensitive adhesive composition according to claim 1, wherein the (B) thermosetting resin is an epoxy resin.

7. The photosensitive adhesive composition according to claim 1, wherein the (A) resin with a carboxyl and/or hydroxyl group has a glass transition temperature of not greater than 150° C. and a weight-average molecular weight of 5000-300000.

8. The photosensitive adhesive composition according to claim 1, wherein the (A) resin with a carboxyl and/or hydroxyl group is an alkali-soluble resin.

9. The photosensitive adhesive composition according to claim 1, wherein the (A) resin with a carboxyl and/or hydroxyl group is a polyimide resin.

10. The photosensitive adhesive composition according to claim 9, wherein the polyimide resin is a polyimide resin obtained by reaction between a tetracarboxylic dianhydride and a diamine component containing a diamine with a carboxyl and/or hydroxyl group in a molecule.

11. The photosensitive adhesive composition according to claim 9, wherein the polyimide resin is a polyimide resin obtained by reaction between a tetracarboxylic dianhydride and an aromatic diamine represented by the following structural formula (2) and/or an aromatic diamine represented by the following structural formula (3):

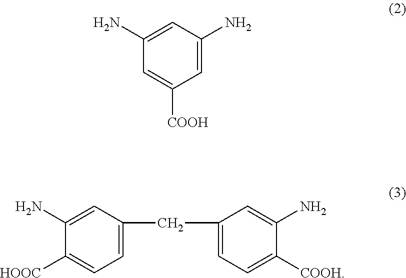

12. The photosensitive adhesive composition according to claim 10, wherein the diamine component further contains an aliphatic etherdiamine represented by the following formula (4) at 10-90 mol % of the total diamine component: 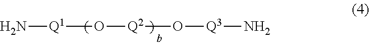
[In the formula, Q¹, Q² and Q³ each independently represent a C1-10 alkylene group, and b represents an integer of 1-80.].

13. The photosensitive adhesive composition according to claim 10, wherein the diamine component further contains a siloxanediamine represented by the following formula (5) at 1-20 mol % of the total diamine component: 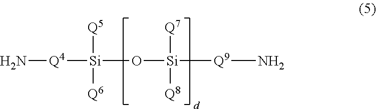
[In the formula, Q⁴ and Q⁹ each independently represent a C1-5 alkylene or optionally substituted phenylene group, Q⁵, Q⁶, Q⁷ and Q⁸ each independently represent a C1-5 alkyl, phenyl or phenoxy group, and d represents an integer of 1-5.].

14. The photosensitive adhesive composition according to claim 9, wherein the polyimide resin is a polyimide resin obtained by reaction between a tetracarboxylic dianhydride and a diamine component, and the tetracarboxylic dianhydride contains a tetracarboxylic dianhydride represented by the following formula (6) at 40 mol % or greater of the total tetracarboxylic dianhydrides:

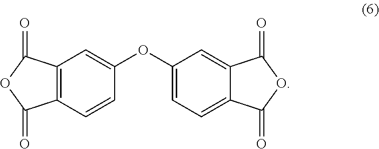

15. A film-like adhesive composed of the photosensitive adhesive composition according to claim 1.

16. An adhesive sheet comprising a base and an adhesive layer composed of the photosensitive adhesive composition according to claim 1 formed on one side of the base.

17. An adhesive sheet comprising the film-like adhesive according to claim 15 and a dicing sheet,
wherein the film-like adhesive and the dicing sheet are laminated.

18. An adhesive pattern formed by forming an adhesive layer composed of the photosensitive adhesive composition according to claim 1 on an adherend, exposing the adhesive layer to light through a photomask, and developing the exposed adhesive layer with an alkali developing solution.

19. A semiconductor wafer with an adhesive layer, comprising a semiconductor wafer and an adhesive layer composed of the photosensitive adhesive composition according to claim 1 formed on one side of the semiconductor wafer.

20. A semiconductor device comprising a supporting member, a semiconductor element mounted on the supporting member and an adhesive layer situated between the supporting member and semiconductor element, wherein the adhesive layer is formed of the photosensitive adhesive composition according to claim 1.

21. A process for producing a semiconductor device, comprising a step of bonding a semiconductor element and a supporting member for mounting a semiconductor element by the photosensitive adhesive composition according to claim 1.
